(19) United States
(12) Patent Application Publication
(10) Pub. No.: US 2025/0081444 A1
(43) Pub. Date: Mar. 6, 2025

(54) SEMICONDUCTOR MEMORY DEVICE AND METHOD FOR MANUFACTURING THE SAME

(71) Applicant: Samsung Electronics Co., Ltd., Suwon-si (KR)

(72) Inventors: Bowon YOO, Suwon-si (KR); Seokhan PARK, Suwon-si (KR); Gyuhwan OH, Suwon-si (KR); Jinwoo HAN, Suwon-si (KR)

(73) Assignee: Samsung Electronics Co., Ltd., Suwon-si (KR)

(21) Appl. No.: 18/610,790

(22) Filed: Mar. 20, 2024

(30) Foreign Application Priority Data
Sep. 5, 2023 (KR) 10-2023-0117905

(51) Int. Cl. H10B 12/00

(52) U.S. Cl. CPC H10B 12/482; H10B 12/315; H10B 12/488; H10B 12/50

(57) ABSTRACT

A semiconductor memory device includes a peripheral gate structure, bit lines above the peripheral gate structure, being apart from each other in a first direction, and extending in a second direction different from the first direction, first and second active patterns above the bit lines and apart from each other in the second direction, first and second word lines between the first and active patterns and being adjacent to the first and second active patterns, respectively, a first back gate electrode corresponding to the first word line, the first active pattern being between the first back gate electrode and the first word line, a second back gate electrode corresponding to the second word line, the second active being between the second back gate electrode and the second word line, and a word line shielding structure between the first word line and the second word line.

### CROSS-REFERENCE TO RELATED APPLICATION

This application claims priority to and the benefit of Korean Patent Application No. 10-2023-0117905 filed at the Korean Intellectual Property Office on Sep. 5, 2023, the entire contents of which are incorporated herein by reference.

### BACKGROUND

### (a) Field

The present disclosure relates to semiconductor memory devices and/or manufacturing methods thereof, and more particularly, to semiconductor memory devices including a vertical channel transistor (VCT) and/or methods for manufacturing (fabricating) the same.

### (b) Description of the Related Art

There is a need to increase the degree of integration of a semiconductor memory device to meet excellent performance and low price required by a consumer. Because the degree of integration of the semiconductor memory device is an important factor in determining a price of a product, an increased degree of integration is particularly required.

Because a degree of integration of a two-dimensional or planar semiconductor memory device is mainly determined by an area occupied by a unit memory cell, the degree of integration of the two-dimensional or planar semiconductor memory device is greatly influenced by a level of fine pattern formation technology. However, because ultra-expensive equipment is required to realize fine patterns, the degree of integration of the two-dimensional semiconductor memory device is increasing but still limited. Accordingly, a semiconductor memory device including a vertical channel transistor in which a channel extends in a vertical direction is being proposed.

### SUMMARY

Some example embodiments of the present disclosure provide semiconductor memory devices and/or methods for manufacturing the same that may further reduce an interval between word lines to improve a degree of integration by controlling coupling between the word lines through a conductive shielding structure, and may implement a word line shielding structure having a complex structure through wafer bonding.

A semiconductor memory device according to an example embodiment of the present disclosure may include a peripheral gate structure on a substrate, bit lines above the peripheral gate structure, the bit lines being spaced apart from each other in a first direction, the bit lines extending in a second direction different from the first direction, a first active pattern and a second active pattern above the bit lines, the first active pattern and the second active pattern being spaced apart from each other in the second direction, a first word line and a second word line between the first active pattern and the second active pattern, the first word line being adjacent to the first active pattern, the second word line being adjacent to the second active pattern, a first back gate electrode corresponding to the first word line, the first active pattern being between the first back gate electrode and the first word line, a second back gate electrode corresponding to the second word line, the second active pattern being between the second back gate electrode and the second word line, and a word line shielding structure between the first word line and the second word line.

A semiconductor memory device according to an example embodiment of the present disclosure may include a peripheral gate structure on a substrate, bit lines that above the peripheral gate structure, the bit lines being spaced apart from each other in a first direction, the bit lines extending in a second direction different from the first direction, a first active pattern and a second active pattern above the bit lines, the first active pattern and the second active pattern being spaced apart from each other in the second direction, a first word line and a second word line between the first active pattern and the second active pattern, the first word line being adjacent to the first active pattern, the second word line being adjacent to the second active pattern, a first back gate electrode corresponding to the first word line, the first active pattern being between the first back gate electrode and the first word line, and a second back gate electrode corresponding to the second word line, the second active pattern being between the second back gate electrode and the second word line, wherein an interval between the first word line and the second word line in the second direction is 6 nm or less.

A semiconductor memory device according to an example embodiment of the present disclosure may include a peripheral gate structure on a substrate, bit lines above the peripheral gate structure, the bit lines being spaced apart from each other in a first direction, the bit lines extending in a second direction different from the first direction, a bit line shielding structure being adjacent to an adjacent one of the bit lines and above the peripheral gate structure, the bit line shielding structure extending in the second direction, a first active pattern and a second active pattern above the bit lines, the first active pattern and the second active pattern being spaced apart from each other in the second direction, a first word line and a second word line between the first active pattern and the second active pattern, the first word line being adjacent to the first active pattern, the second word line being adjacent to the second active pattern, a first back gate electrode corresponding to the first word line, the first active pattern being between the first back gate electrode and the first word line, a second back gate electrode corresponding to the second word line, the second active pattern being between the second back gate electrode and the second word line, and a word line shielding structure between the first word line and the second word line, wherein an interval between the first word line and the second word line in the second direction is 6 nm or less.

The semiconductor memory device and the method for manufacturing the same according to some example embodiments may further reduce an interval between word lines to improve a degree of integration by controlling coupling between the word lines through a conductive shielding structure and may implement a word line shielding structure having a complex structure through wafer bonding.

### BRIEF DESCRIPTION OF THE DRAWINGS

FIG. 1 is a schematic layout diagram of a semiconductor memory device according to an example embodiment.

FIG. 2 is a plan view of a cell array region of FIG. 1, according to an example embodiment.

FIG. 3 is cross-sectional views cut along lines A-A and B-B of FIG. 2, according to an example embodiment.

FIG. 4 shows cross-sectional views cut along lines C-C and D-D of FIG. 2 and a cross-sectional view of a peripheral circuit region, according to an example embodiment.

FIG. 5 is an enlarged cross-sectional view of a portion P of FIG. 3.

FIG. 6 is an enlarged cross-sectional view of a portion Q of FIG. 4.

FIGS. 7 to 85 are views for describing a method for manufacturing the semiconductor memory device according to an example embodiment.

### DETAILED DESCRIPTION

The present disclosure will be described more fully hereinafter with reference to the accompanying drawings, in which some example embodiments of the disclosure are shown. As those skilled in the art would realize, the described example embodiments may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and example embodiments of the present disclosure are not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it may be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

In addition, throughout the specification, two directions parallel to an upper surface of a substrate and intersecting each other are defined as a first direction D1 and a second direction D2 and a direction perpendicular to the upper surface of the substrate is defined as a third direction D3. For example, the first direction D1 and the second direction D2 may be perpendicular to each other.

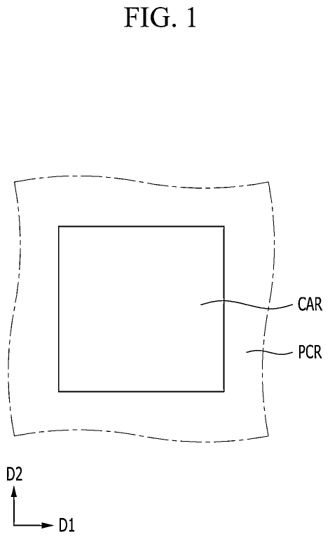

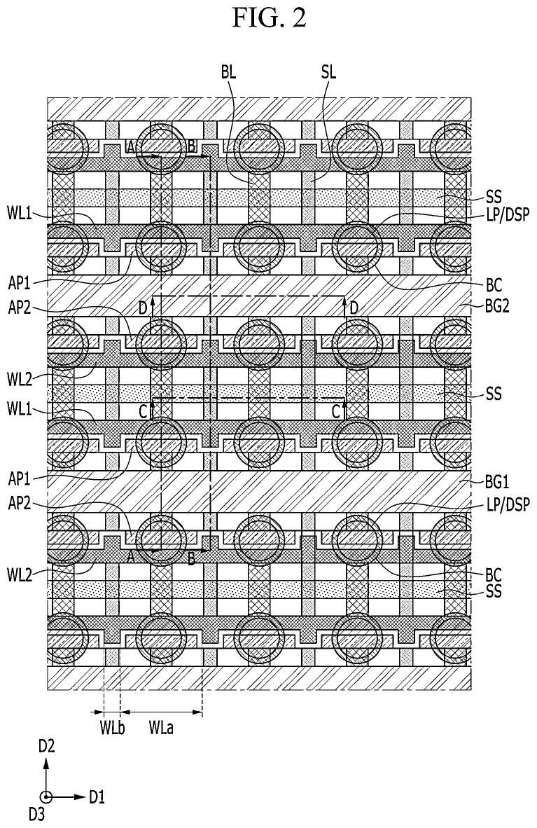

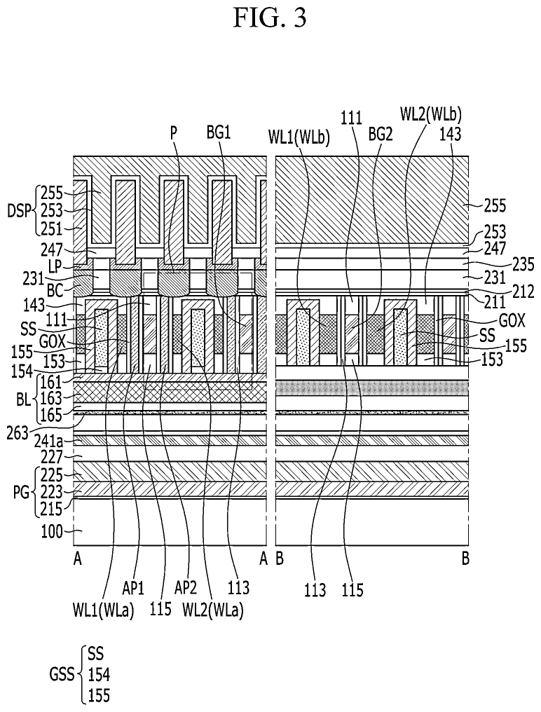

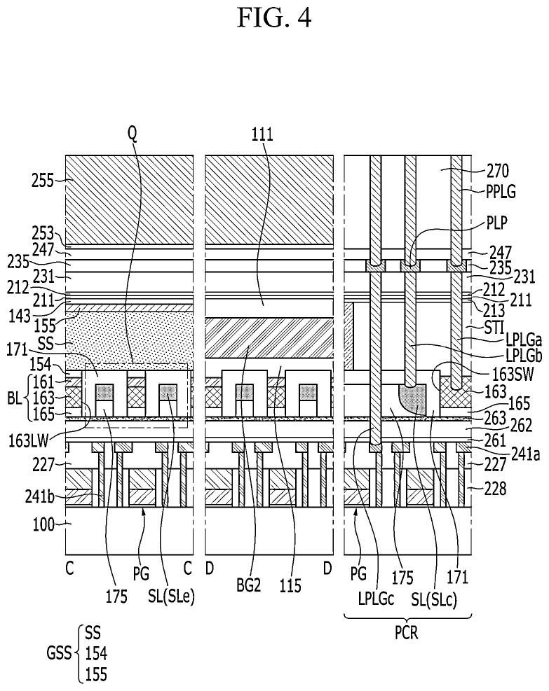

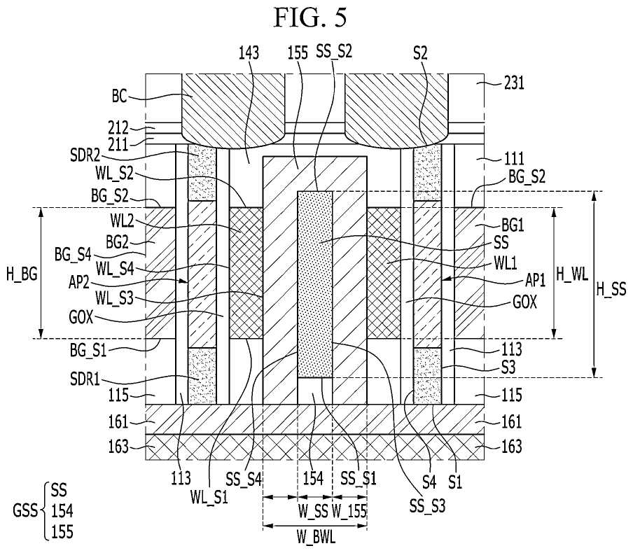

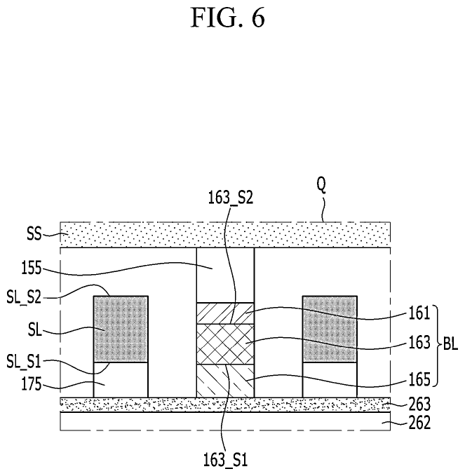

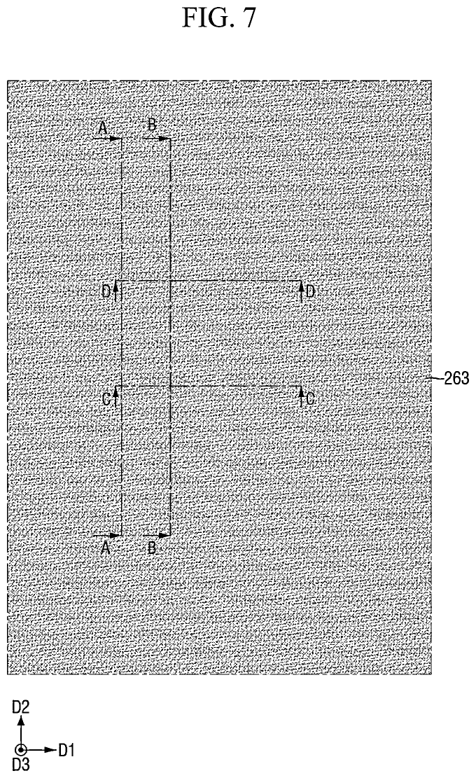

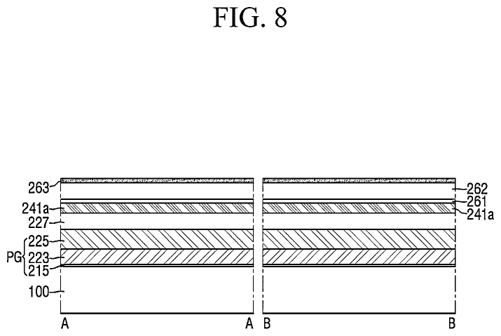

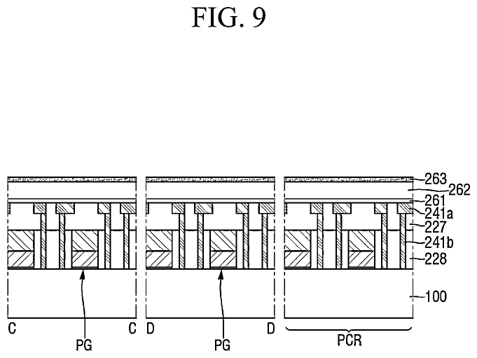

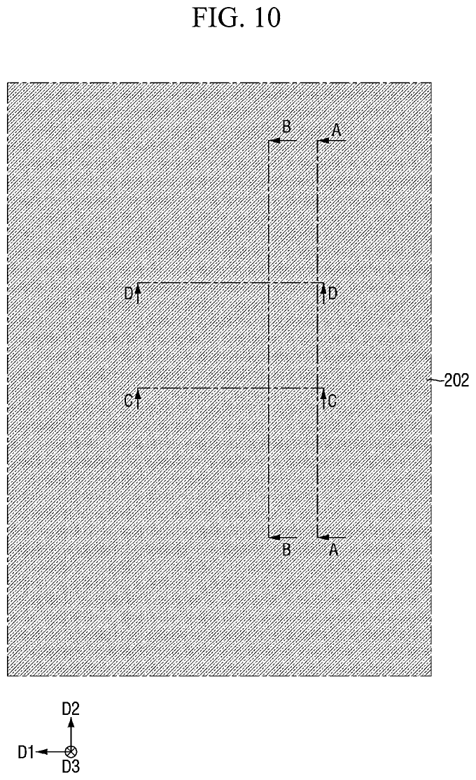

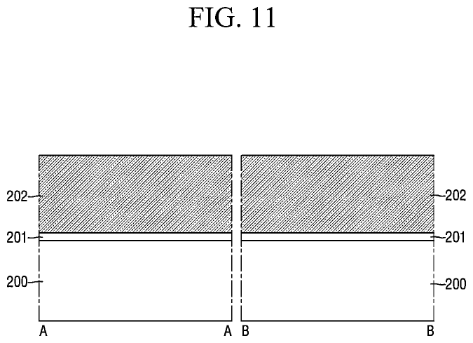

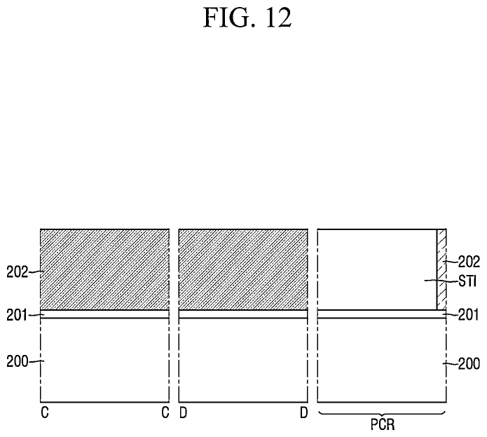

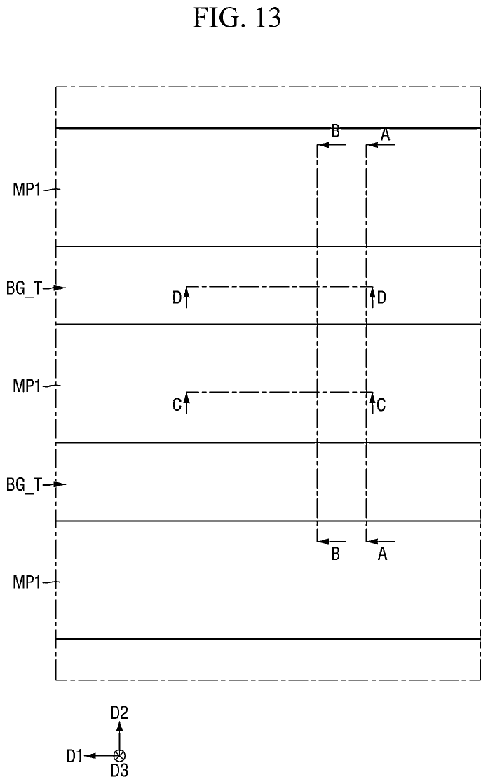

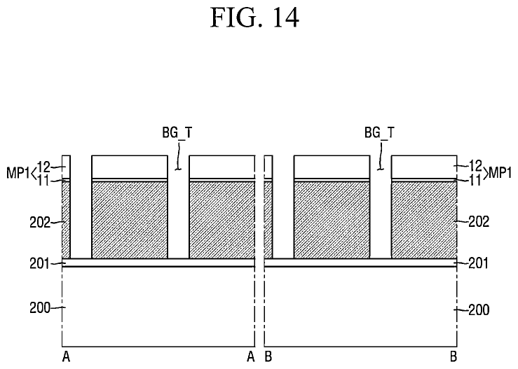

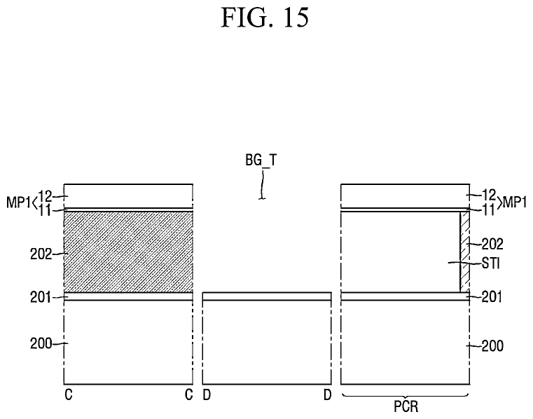

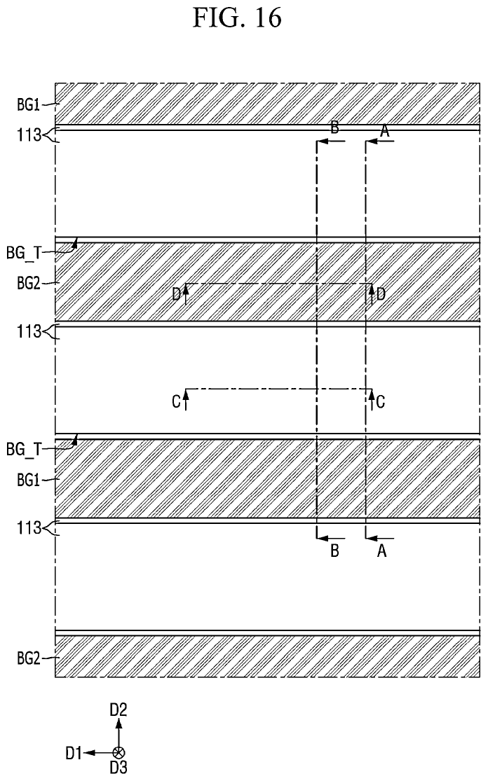

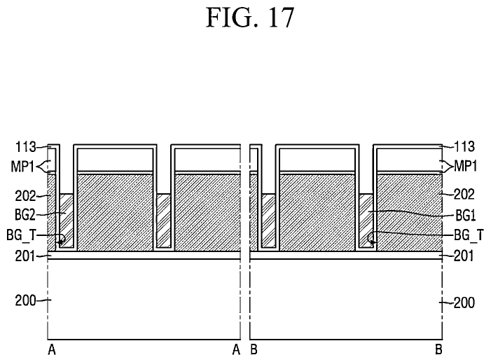

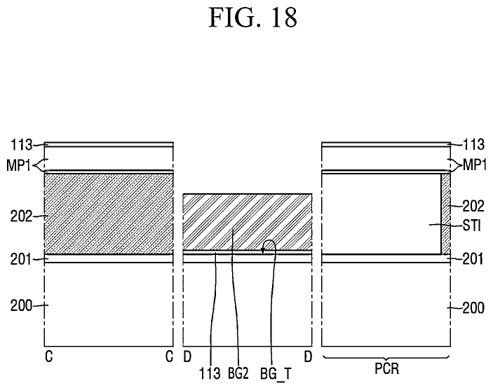

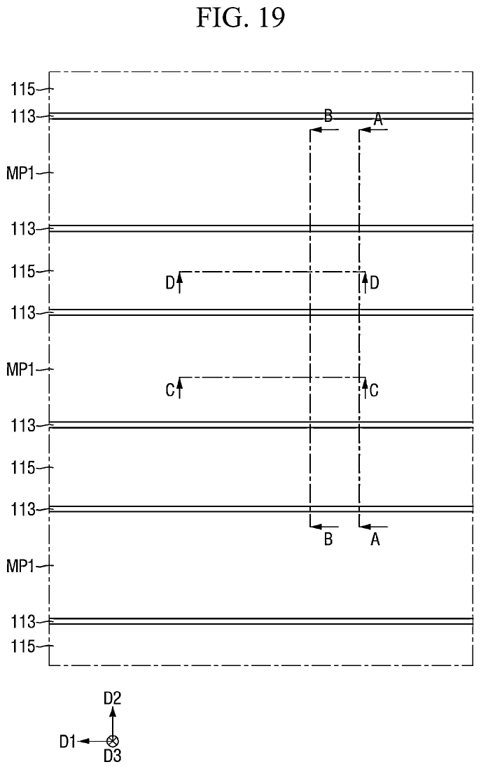

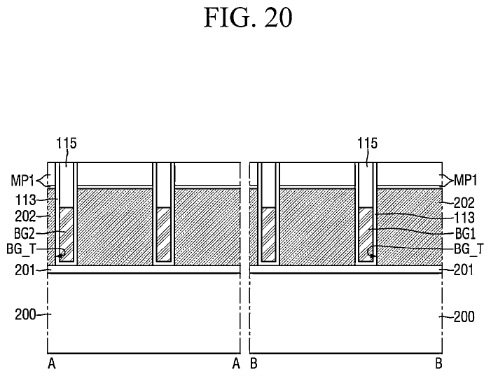

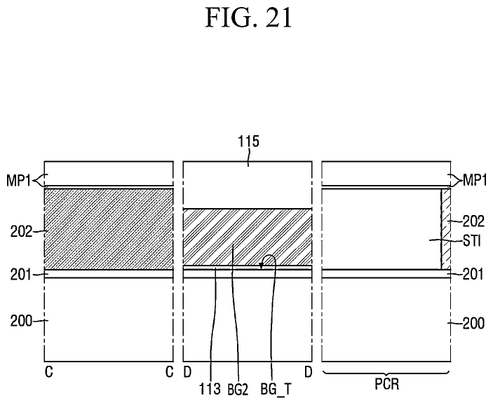

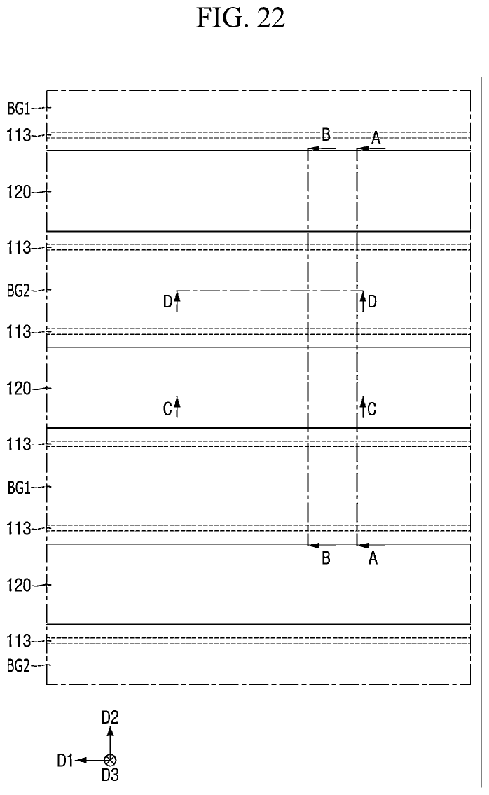

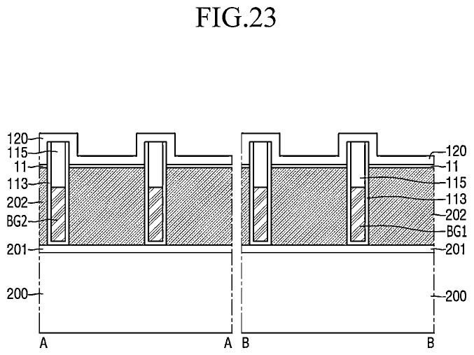

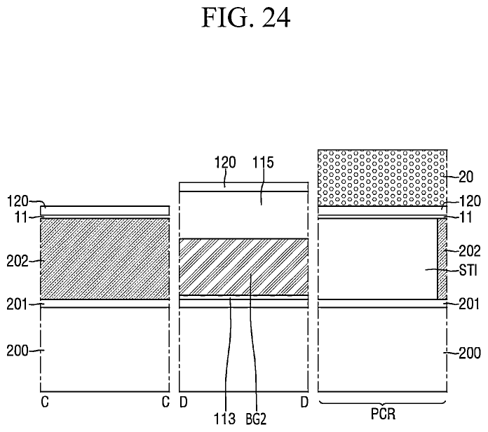

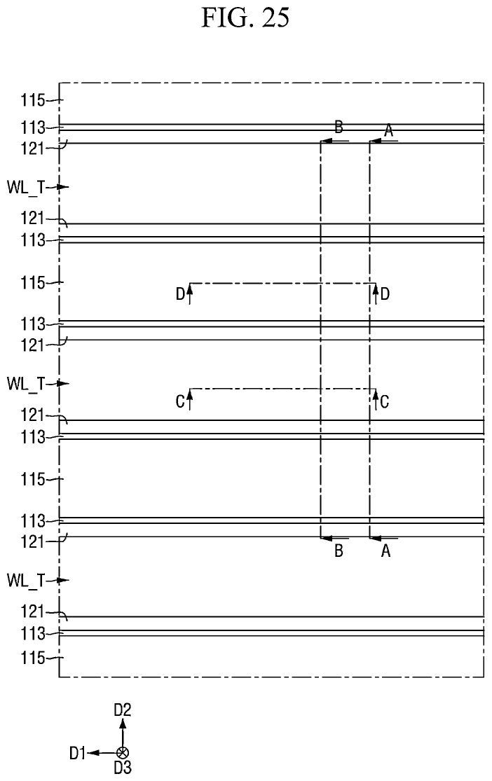

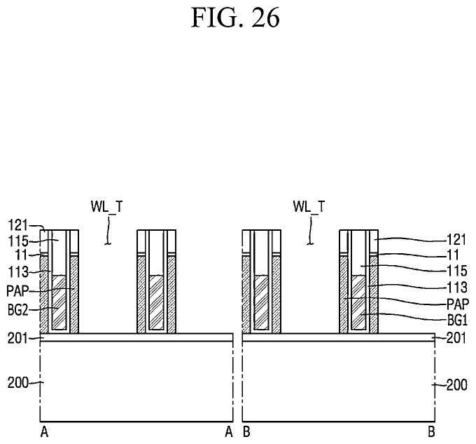

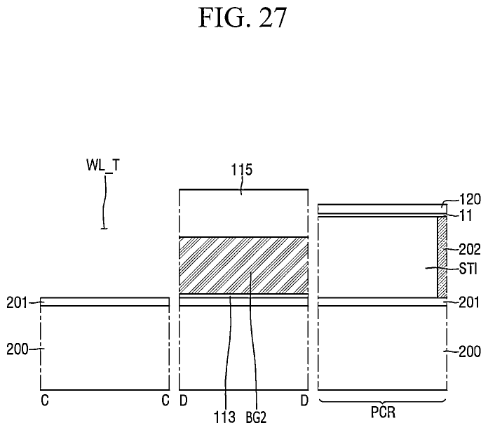

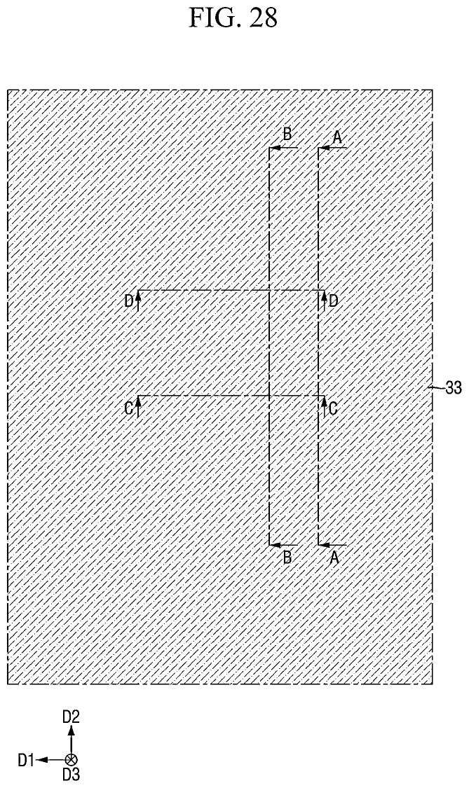

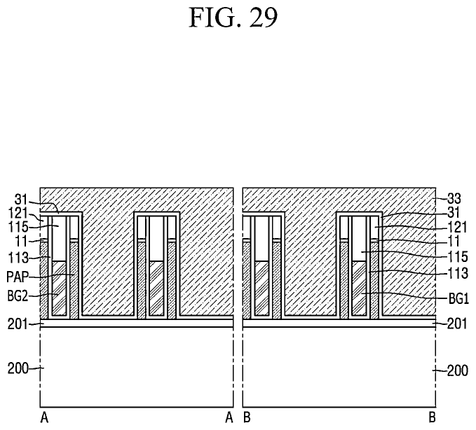

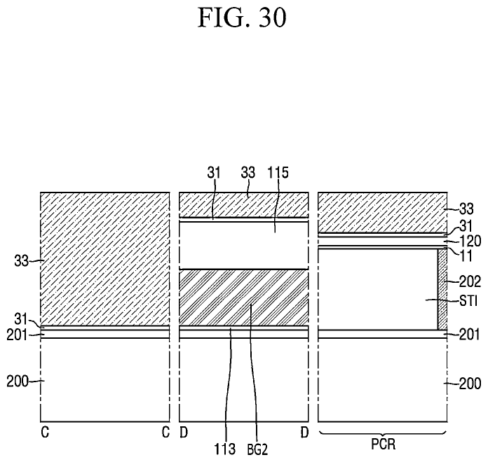

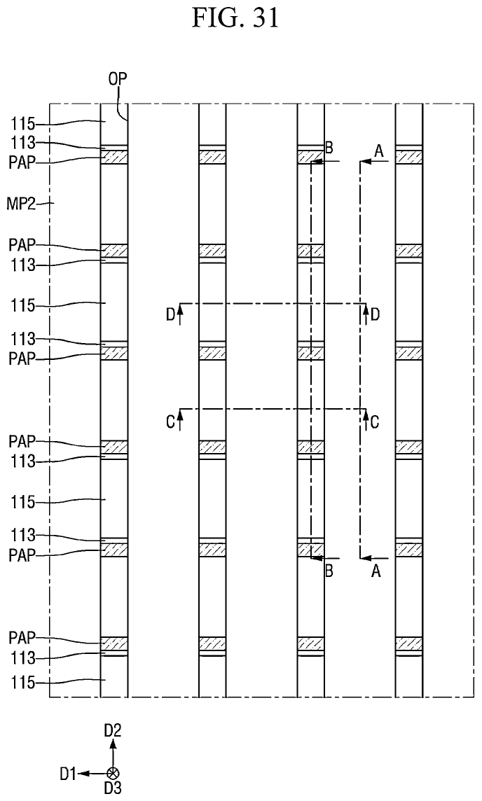

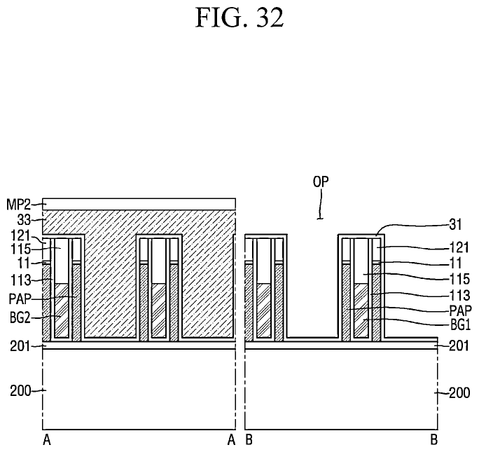

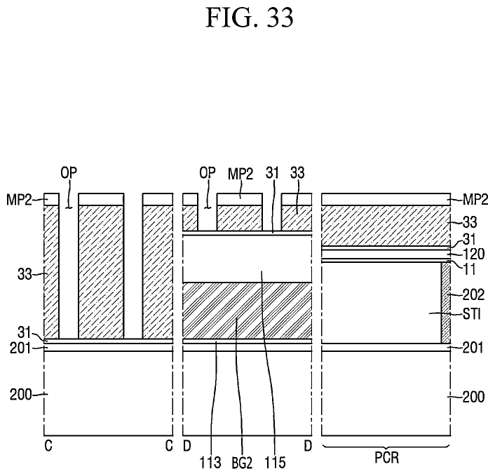

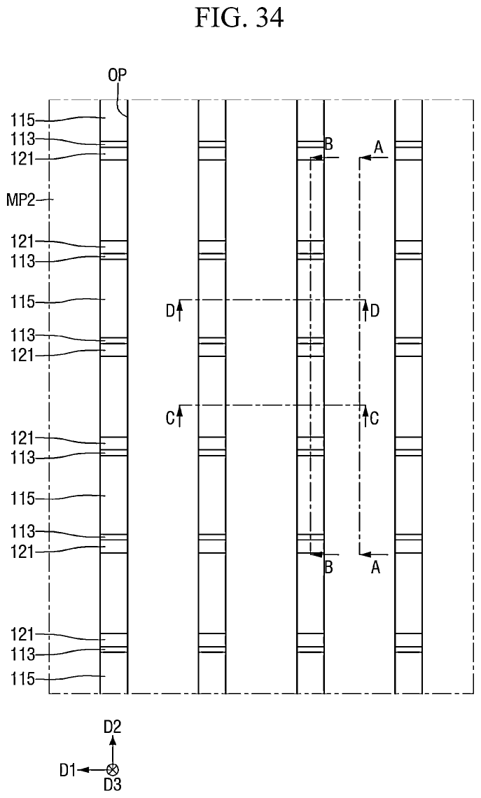

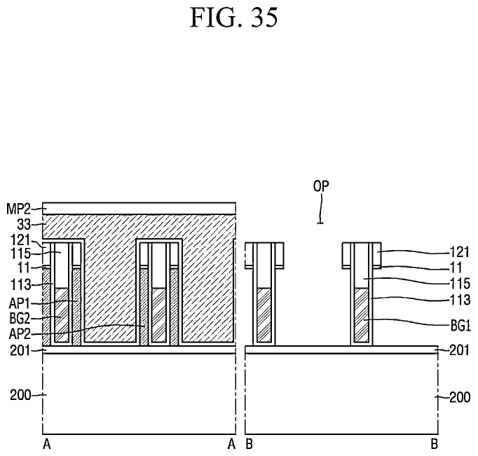

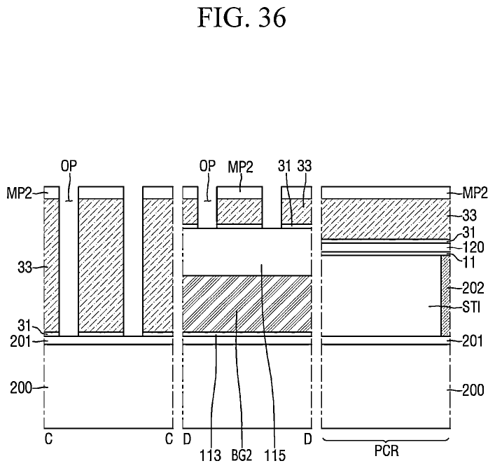

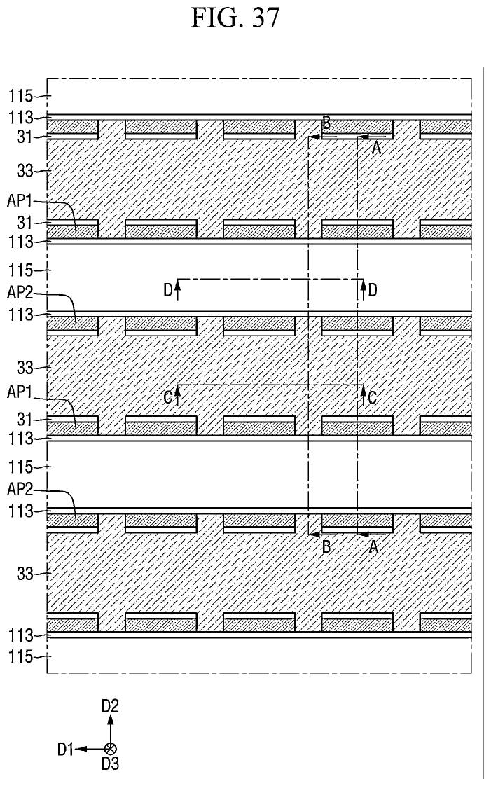

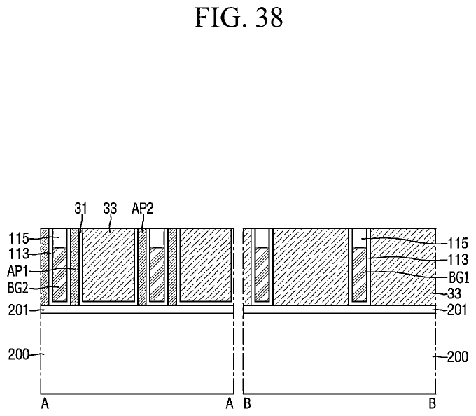

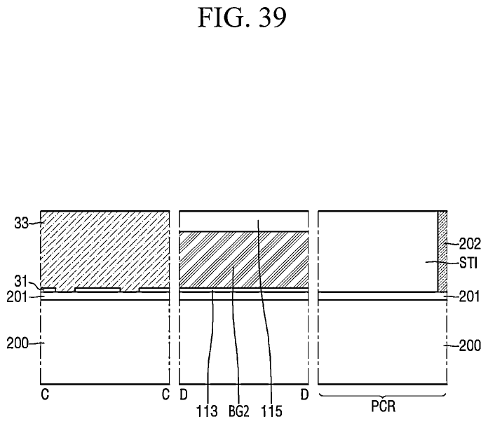

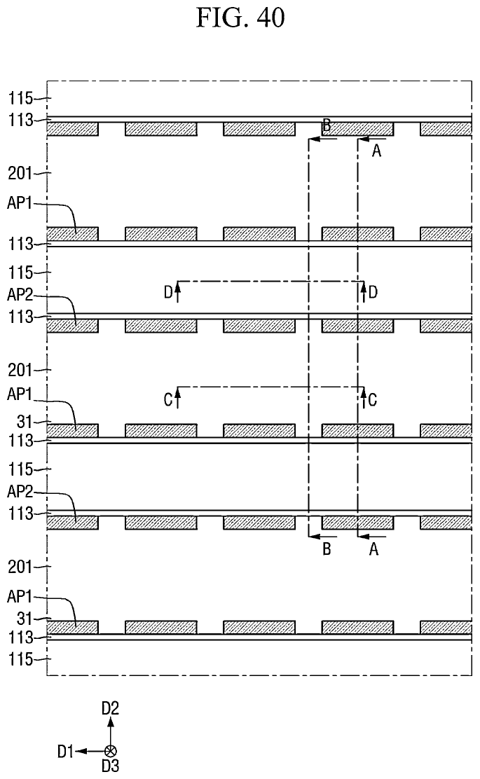

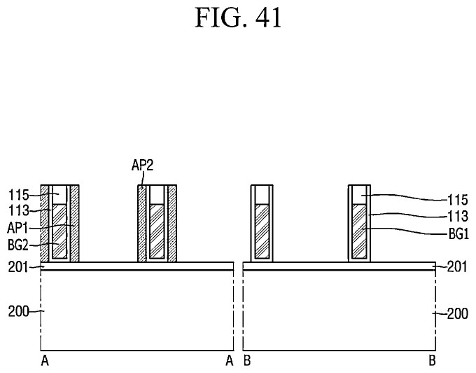

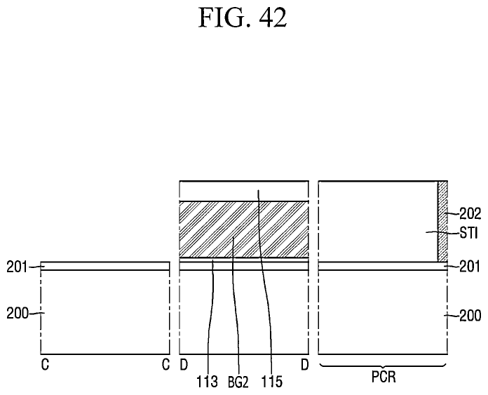

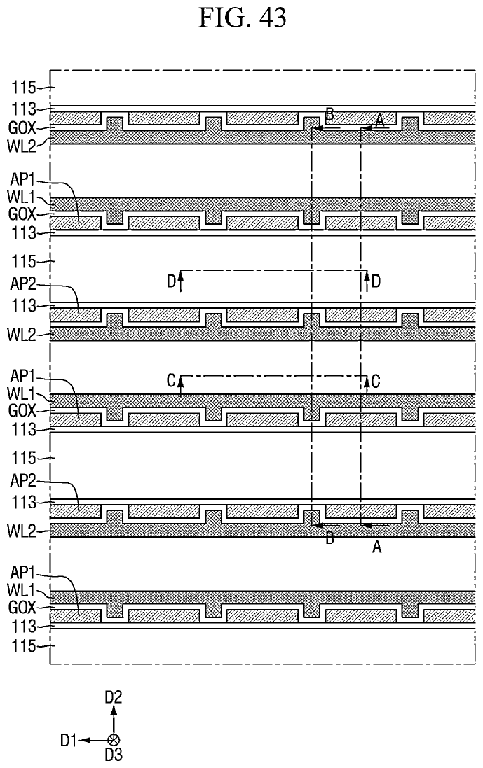

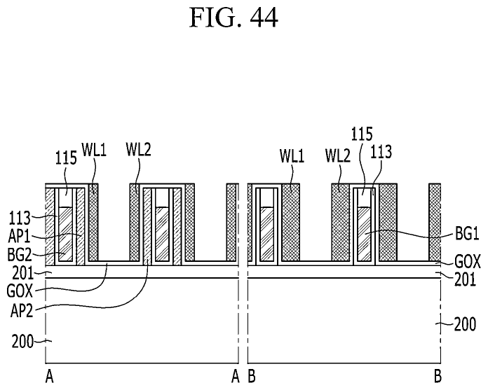

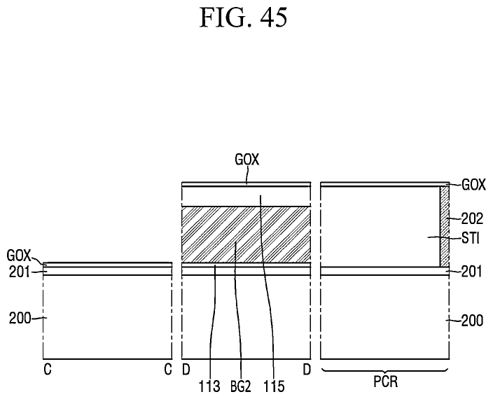

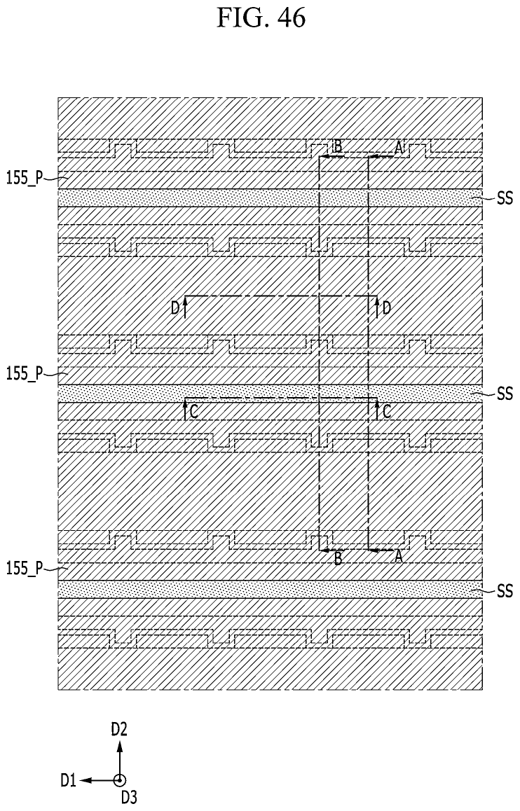

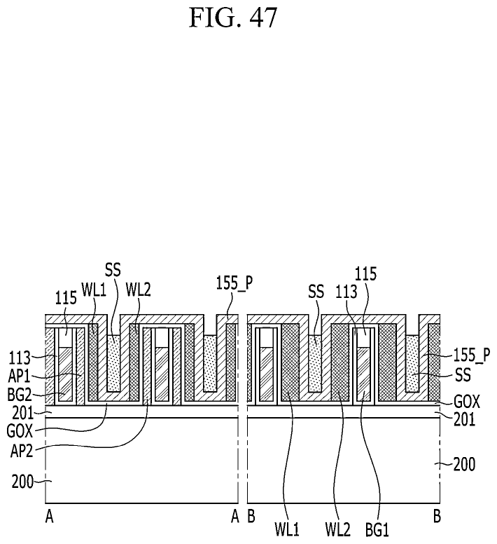

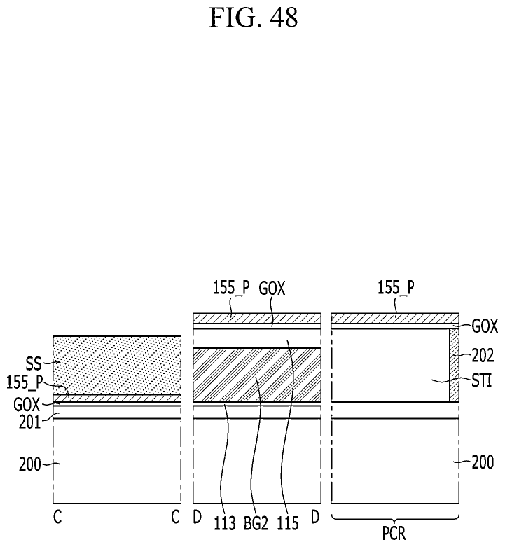

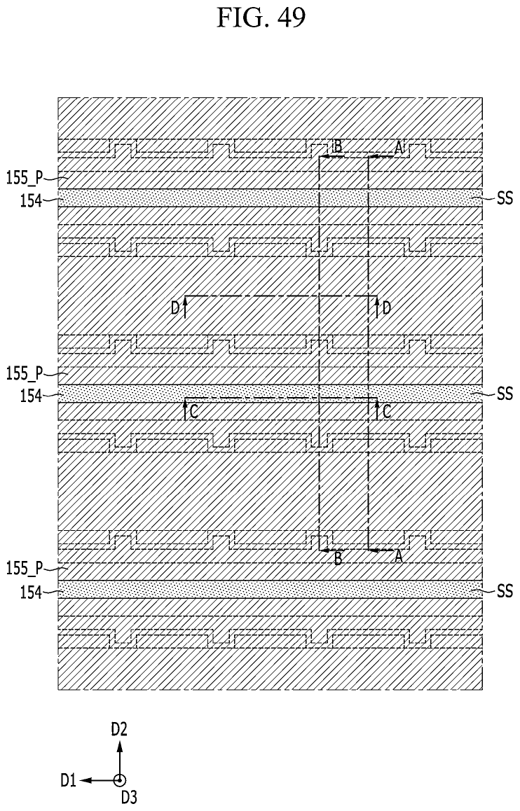

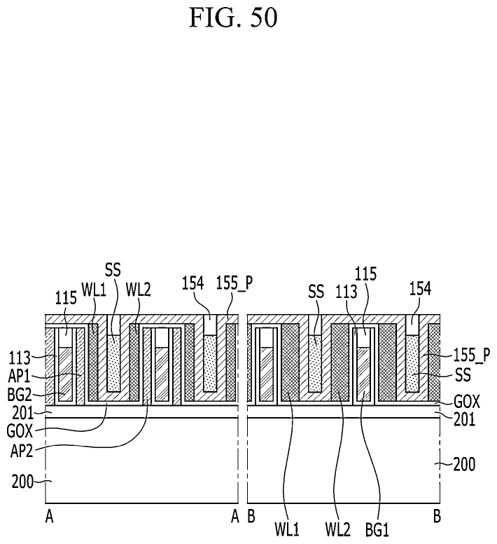

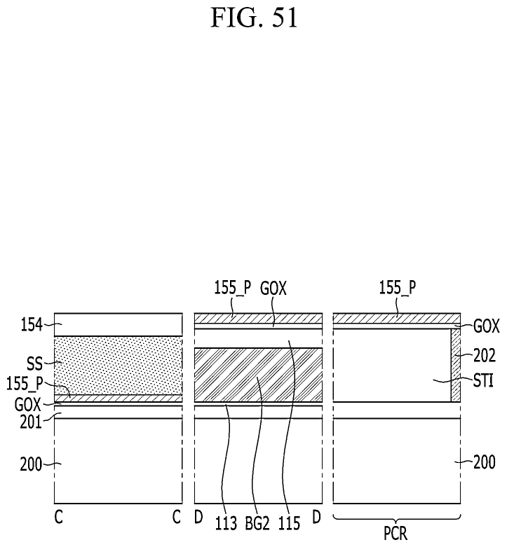

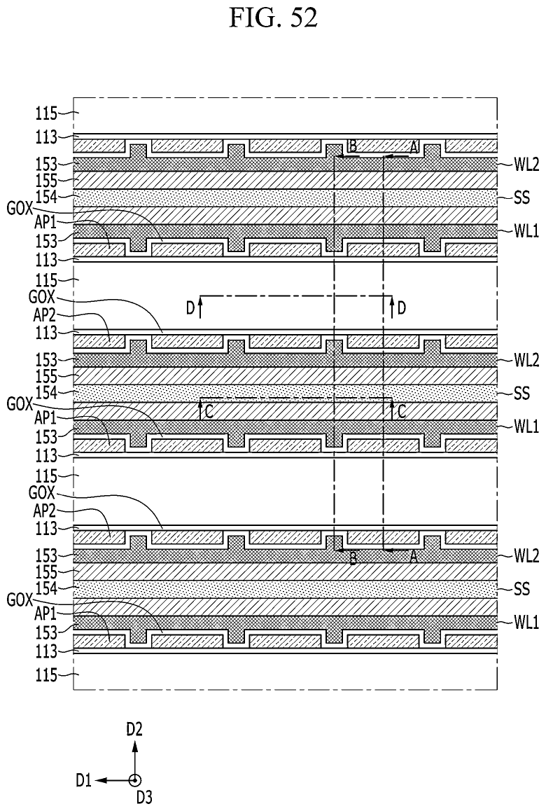

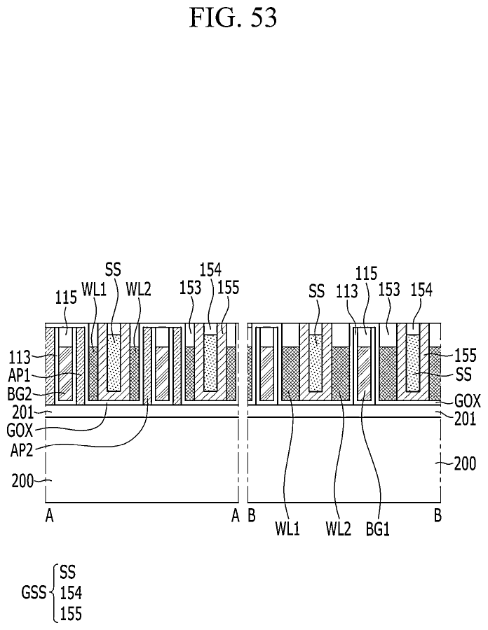

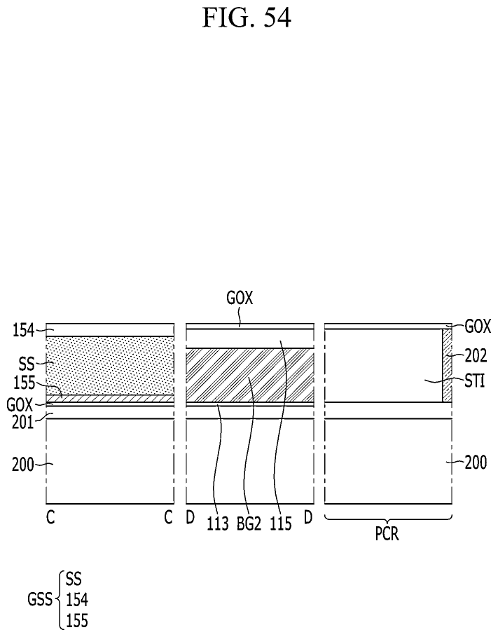

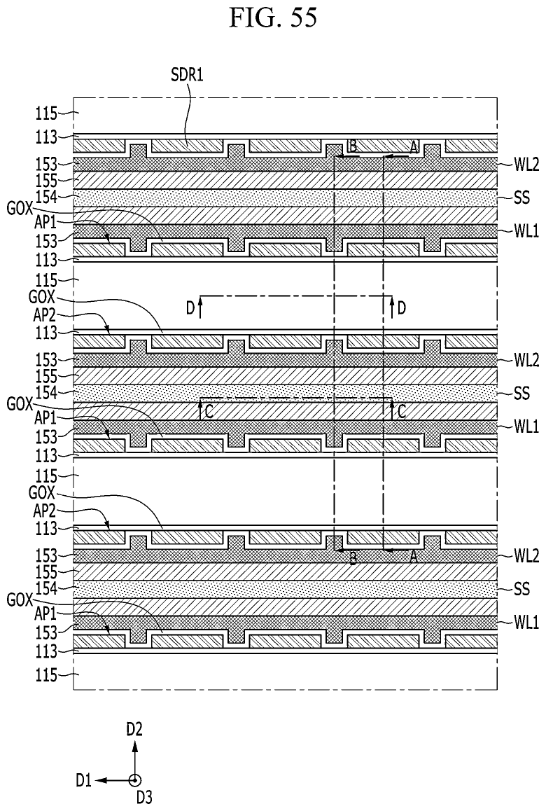

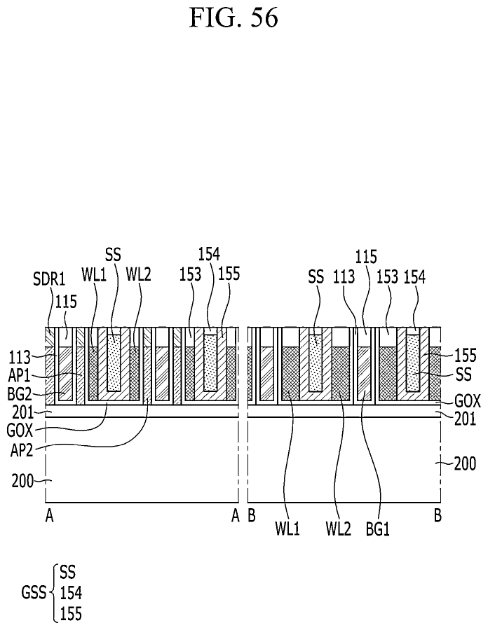

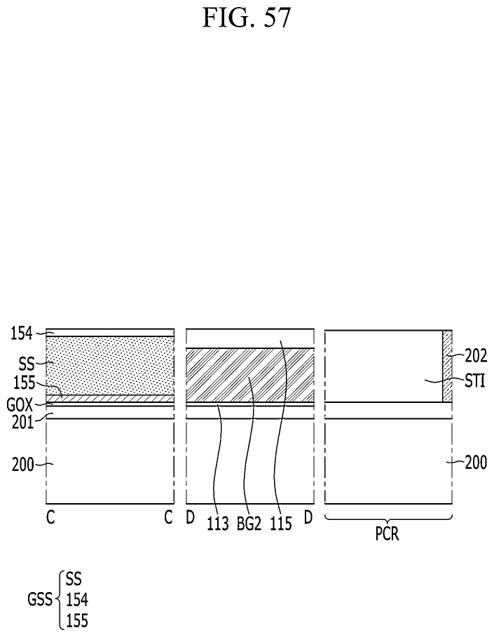

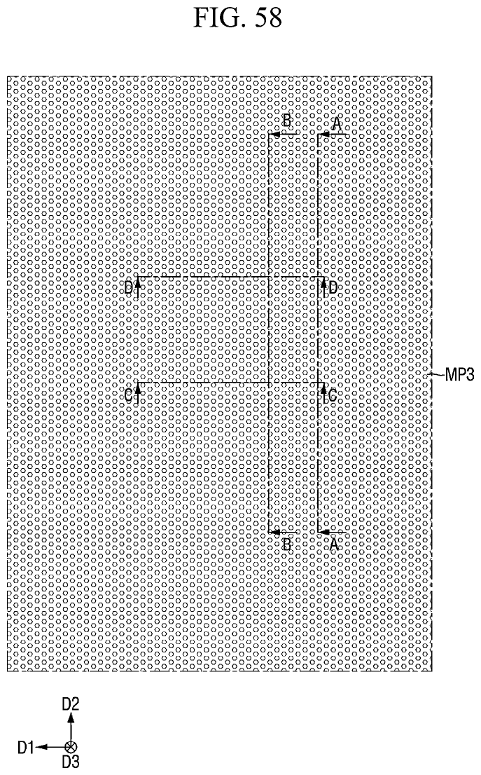

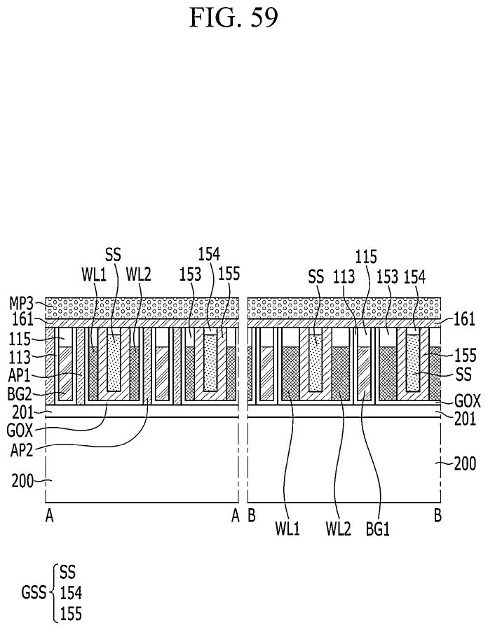

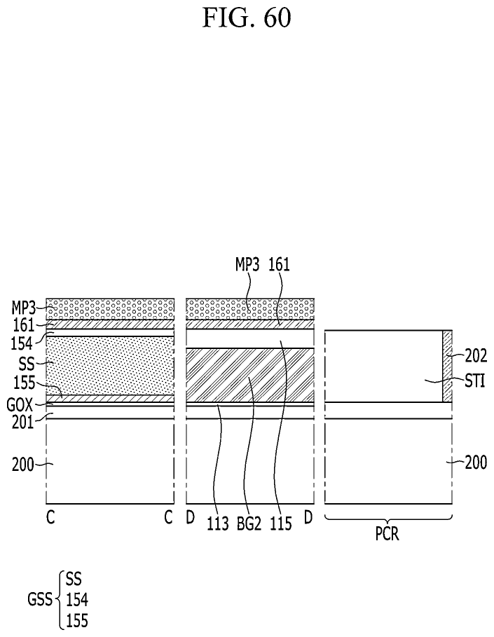

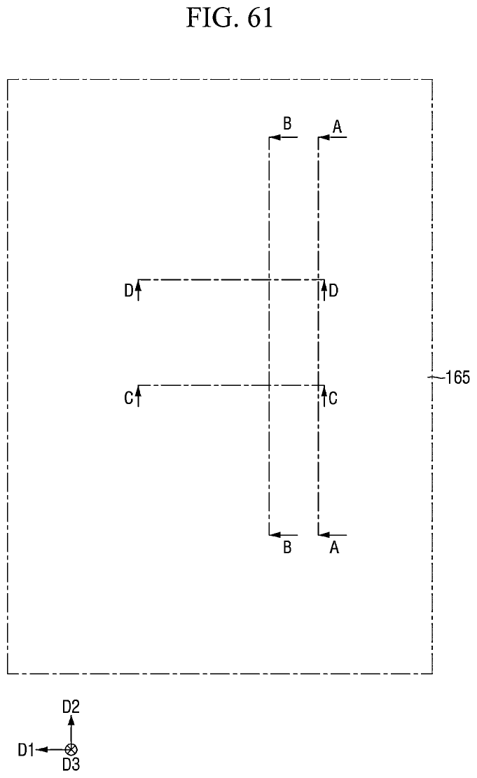

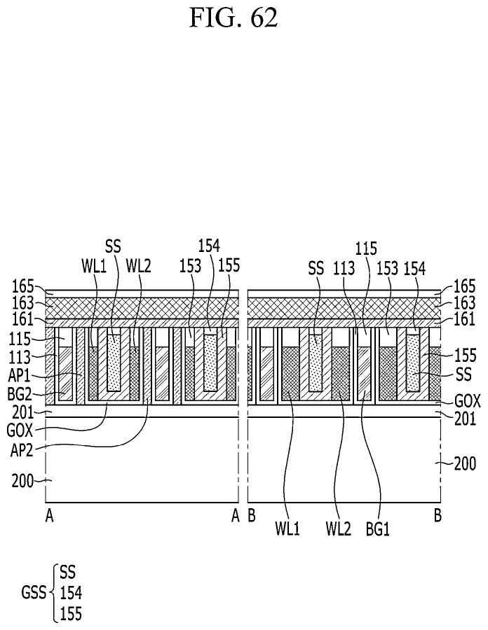

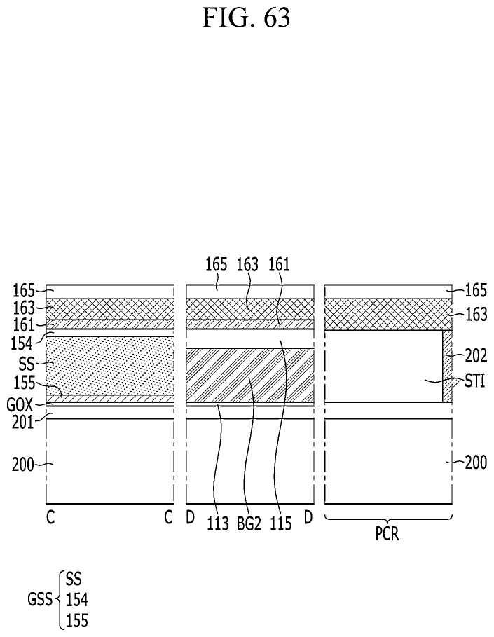

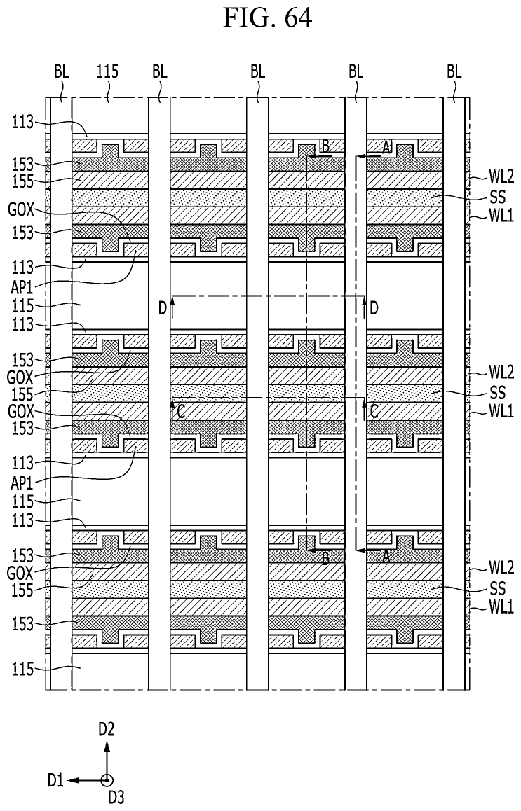

FIG. 1 is a schematic layout diagram of a semiconductor memory device according to an example embodiment. FIG. 2 is a plan view of a cell array region of FIG. 1, according to an example embodiment. FIG. 3 is a cross-sectional view cut along lines A-A and B-B of FIG. 2, according to an example embodiment. FIG. 4 shows cross-sectional views cut along lines C-C and D-D of FIG. 2 and a cross-sectional view of a peripheral circuit region, according to an example embodiment. FIG. 5 is an enlarged cross-sectional view of a portion P of FIG. 3. FIG. 6 is an enlarged cross-sectional view of a portion Q of FIG. 4. For reference, FIG. 4 includes a cross-sectional view of a peripheral circuit region bordering the cell array region of FIG. 1.

The semiconductor memory device according to some example embodiments may include a memory cell that includes a vertical channel transistor (VCT).

Referring to FIGS. 1 to 6, the semiconductor memory device according to some example embodiments may include a peripheral gate structure PG, bit lines BL, word lines WL1 and WL2, first and second back gate electrodes BG1 and BG2, a word line shielding structure GSS, active patterns (or activation patterns) AP1 and AP2, and data storage patterns DSP.

The substrate 100 may include the cell array region CAR and the peripheral circuit region PCR. Memory cells may be disposed above or on the substrate 100 of the cell array region CAR.

The substrate 100 may be a silicon substrate, or may include another material such as silicon germanium, indium antimonide, a lead tellurium compound, indium arsenic, indium phosphide, gallium arsenic, or gallium antimonide, but example embodiments of the present disclosure are not limited thereto.

The peripheral gate structure PG may be disposed on the substrate 100. The peripheral gate structure PG may be disposed across the cell array region CAR and the peripheral circuit region PCR. In other words, a portion of the peripheral gate structure PG may be disposed at the cell array region CAR of the substrate 100, and the remainder of the peripheral gate structure PG may be disposed at the peripheral circuit region PCR of the substrate 100.

The peripheral gate structure PG may be included in a sensing transistor, a transmission transistor, a driving transistor, and the like. For example, the peripheral gate structure PG included in the sensing transistor may be disposed on the substrate 100 of the cell array region CAR, but example embodiments of the present disclosure are not limited thereto. A type of a transistor of a peripheral circuit disposed above or on the substrate 100 of the cell array region CAR may vary depending on design disposition of the semiconductor memory device.

The peripheral gate structure PG may include a peripheral gate insulating film 215, a peripheral gate conduction pattern 223, and a peripheral gate mask pattern 225. The peripheral gate insulating film 215 may include a silicon oxide film, a silicon oxynitride film, a high dielectric constant insulating film having a higher dielectric constant than the silicon oxide film, or a combination thereof. For example, the high dielectric constant insulating film may include metal oxide, metal oxynitride, metal silicon oxide, metal silicon oxynitride, or a combination thereof, but example embodiments of the present disclosure are not limited thereto. The peripheral gate conduction pattern 223 may include a conductive material, and for example, the peripheral gate conduction pattern 223 may include a doped semiconductor material, conductive metal nitride, conductive metal silicon nitride, metal carbonitride, conductive metal silicide, conductive metal oxide, a two-dimensional (2D) material, a metal, or a combination thereof. The peripheral gate mask pattern 225 is made of an insulating material. In the semiconductor memory device according to some example embodiments, the two-dimensional material may be a metallic material and/or a semiconductor material. The two-dimensional material may include a two-dimensional allotrope or a two-dimensional compound, and for example, the two-dimensional material may include graphene, molybdenum sulfide (MoS₂), molybdenum diselenide (MoSe₂), tungsten diselenide (WSe₂), tungsten sulfide (WS₂), or a combination thereof, but example embodiments of the present disclosure are not limited thereto. In other words, because the above-described two-dimensional material is listed only as an example, two-dimensional materials that may be included in the semiconductor memory devices of example embodiments of the present disclosure are not limited by the above-described material.

A first peripheral lower insulating film 227 and a second peripheral lower insulating film 228 are disposed above or on the substrate 100. Each of the first peripheral lower insulating film 227 and the second peripheral lower insulating film 228 may be made of an insulating material.

A peripheral wire line 241a and a peripheral contact plug 241b may be disposed at the first peripheral lower insulating film 227 and the second peripheral lower insulating film 228. Although the peripheral wire line 241a and the peripheral contact plug 241b are shown as different films, example embodiments of the present disclosure are not limited thereto. A boundary between the peripheral wire line 241a and the peripheral contact plug 241b may not be distinguished. Each of the peripheral wire line 241a and the peripheral contact plug 241b includes a conductive material.

A first peripheral upper insulating film 261 and a second peripheral upper insulating film 262 may be disposed above or on the peripheral wire line 241 a and the peripheral contact plug 241b. Each of the first peripheral upper insulating film 261 and the second peripheral upper insulating film 262 may be made of an insulating material. Unlike the drawings, a peripheral upper insulating film formed of a single film may be disposed above or on the peripheral wire line 241 a and the peripheral contact plug 241b.

A bonding insulating film 263 is disposed on the second peripheral upper insulating film 262. The bonding insulating film 263 may be used to bond a wafer. For example, the bonding insulating film 263 may include silicon carbonitride (SiCN).

The bit lines BL may be disposed above the peripheral gate structure PG. For example, the bit lines BL may be disposed on the bonding insulating film 263.

The bit line BL may extend long in the second direction D2. Adjacent bit lines BL may be spaced apart in the first direction D1. The bit line BL includes a long side wall 163LW extending in the second direction D2 and a short side wall 163SW extending in the first direction D1.

Each bit line BL may extend from the cell array region CAR to the peripheral circuit region PCR. An end portion of each bit line BL may be disposed on the peripheral circuit region PCR. A portion of the bit line BL may be disposed at a position that overlaps the peripheral circuit region PCR.

Each bit line BL may include a bit line mask pattern 165, a metal pattern 163, and a polysilicon pattern 161 sequentially stacked in the third direction D3. Unlike the drawings, the bit line BL may include one of the polysilicon pattern 161 and the metal pattern 163.

The bit line BL may include a conductive bit line. The conductive bit line includes a film made of a conductive material. The conductive bit line may include the polysilicon pattern 161 and the metal pattern 163.

The metal pattern 163 may include a conductive material, and for example, the metal pattern 163 may include conductive metal nitride, conductive metal silicon nitride, metal carbonitride, conductive metal silicide, conductive metal oxide, a two-dimensional material, a metal, or a combination thereof. The bit line mask pattern 165 may include an insulating material such as silicon nitride, silicon oxynitride, or the like.

In FIG. 4, the polysilicon pattern 161 of the bit line BL is not being disposed at the peripheral circuit region PCR, but example embodiments of the present disclosure are not limited thereto.

A bit line shielding structure 171, SL, and 175 is disposed above the peripheral gate structure PG. The bit line shielding structure 171, SL, and 175 may be disposed on the bonding insulating film 263, and may be in contact with the bonding insulating film 263.

The bit line shielding structure 171, SL, and 175 is disposed adjacent to the bit line BL. In the cell array region CAR, the bit line shielding structure 171, SL, and 175 may be disposed adjacent to the bit line BL in the first direction D1. That is, the bit line shielding structure 171, SL, and 175 is disposed between adjacent bit lines BL in the first direction D1. The bit line shielding structure 171, SL, and 175 may extend in the second direction D2. The bit line shielding structure 171, SL, and 175 may contact the bit line BL.

The bit line shielding structure 171, SL, and 175 may include the bit line shielding conductive pattern SL and the bit line shielding insulating films 171 and 175. The bit line shielding insulating films 171 and 175 may include the bit line shielding insulating liner 171 and the bit line shielding insulating capping film 175.

The bit line shielding insulating films 171 and 175 may surround a circumference of the bit line shielding conductive pattern SL. In other words, the bit line shielding conductive pattern SL may be disposed inside the bit line shielding insulating films 171 and 175.

The bit line shielding conductive pattern SL may include an extension portion Sle and a connection portion SLc. The extension portion Sle of the bit line shielding conductive pattern SL may extend along the long side wall 163LW of the bit line. The extension portion Sle of the bit line shielding conductive pattern SL may extend in the second direction D2. The bit line shielding conductive pattern SL disposed between the bit lines BL adjacent in the first direction D1 may be the extension portion Sle of the bit line shielding conductive pattern SL.

The connection portion SLc of the bit line shielding conductive pattern SL may extend along the short side wall 163SW of the bit line. The connection portion SLc of the bit line shielding conductive pattern SL may extend in the first direction D1. The connection portion SLc of the bit line shielding conductive pattern SL may connect extension portions Sle of bit line shielding conductive patterns SL adjacent in the first direction D1. The connection portion SLc of the bit line shielding conductive pattern SL is directly connected to the extension portion Sle of the bit line shielding conductive pattern SL.

The bit line shielding conductive pattern SL may extend from the cell array region CAR to the peripheral circuit region PCR. An end portion of the bit line shielding conductive pattern SL may be disposed on the peripheral circuit region PCR. The connection portion SLc of the bit line shielding conductive pattern SL may be disposed on the peripheral circuit region PCR.

The bit line shielding conductive pattern SL may include a conductive material, and for example, the bit line shielding conductive pattern SL may include at least one of conductive metal nitride, conductive metal silicon nitride, metal carbonitride, conductive metal silicide, conductive metal oxide, a two-dimensional material, and a metal.

Each of the bit line shielding insulating liner 171 and the bit line shielding insulating capping film 175 may be made of an insulating material. If the bit line shielding insulating liner 171 and the bit line shielding insulating capping film 175 include the same material, a boundary between the bit line shielding insulating liner 171 and the bit line shielding insulating capping film 175 may not be distinguished.

The bit line shielding structure 171, SL, and 175 may be disposed between adjacent bit lines BL in the first direction D1 so that a coupling noise between the bit lines BL is reduced.

In FIGS. 4 and 6, the bit line shielding conductive pattern SL may have a first surface SL_S1 and a second surface SL_S2 that are opposite to each other in the third direction D3. For example, the first surface SL_S1 of the bit line shielding conductive pattern SL and the second surface SL_S2 of the bit line shielding conductive pattern SL may be included in the extension portion Sle of the bit line shielding conductive pattern SL. The metal pattern 163 of the bit line BL may have a first surface 163_S1 and a second surface 163_S2 that are opposite to each other in the third direction D3. The first surface SL_S1 of the bit line shielding conductive pattern SL and the first surface 163_S1 of the metal pattern 163 are closer to the bonding insulating film 263 than the second surface SL_S2 of the bit line shielding conductive pattern SL and the second surface 163_S2 of the metal pattern 163. The third direction D3 may be a thickness direction of the substrate 100.

In FIGS. 4 and 6, a length of the extension portion Sle of the bit line shielding conductive pattern SL in the third direction D3 based on the bonding insulating film 263 may be equal to or greater than a length of the metal pattern 163 of the bit line BL in the third direction D3 based on the bonding insulating film 263. In addition, a height of the first surface SL_S1 of the extension portion Sle of the bit line shielding conductive pattern SL based on the bonding insulating film 263 may be equal to or less than a height of the first surface 163_S1 of the metal pattern 163 of the bit line BL based on the bonding insulating film 263, and a height of the second surface SL_S2 of the extension portion Sle of the bit line shielding conductive pattern SL based on the bonding insulating film 263 may be equal to or greater than a height of the second surface 163_S2 of the metal pattern 163 of the bit line BL based on the bonding insulating film 263. That is, the extension portion Sle of the bit line shielding conductive pattern SL may extend in the third direction D3, and may extend to overlap the metal pattern 163 of the bit line BL in the first direction D1. Accordingly, the semiconductor memory device may control coupling between the bit lines BL through the bit line shielding structure 171, SL, and 175.

The first active patterns AP1 and the second active patterns AP2 may be disposed above each bit line BL. The first active patterns AP1 and the second active patterns AP2 may be alternately disposed along the second direction D2.

The first active patterns AP1 may be spaced apart from each other in the first direction D1. The first active patterns AP1 may be spaced apart at regular intervals. The second active patterns AP2 may be spaced apart from each other in the first direction D1. The second active patterns AP2 may be spaced apart at regular intervals. That is, the first and second active patterns AP1 and AP2 may be two-dimensionally disposed along the first direction D1 and the second direction D2 that intersect each other.

For example, each of the first active pattern AP1 and the second active pattern AP2 may be made of a monocrystalline semiconductor material. As an example, each of the first active pattern AP1 and the second active pattern AP2 may be made of monocrystalline silicon.

Each of the first active pattern AP1 and the second active pattern AP2 may have a length in the first direction D1, a width in the second direction D2, and a height in the third direction D3. Each of the first active pattern AP1 and the second active pattern AP2 may have a substantially uniform width. That is, each of the first active pattern AP1 and the second active pattern AP2 may have substantially equivalent widths on first and second surfaces S1 and S2. Additionally, the width of the first active pattern AP1 may be the same as the width of the second active pattern AP2.

Each of the width of the first active pattern AP1 and the width of the second active pattern AP2 may range from several nm to several tens of nm. For example, each of the width of the first active pattern AP1 and the width of the second active pattern AP2 may be 1 nm to 30 nm or 1 nm to 10 nm, but example embodiments of the present disclosure are not limited thereto. A length of each of the first and second active patterns AP1 and AP2 may be larger than a line width of the bit line BL. That is, the length of each of the first and second active patterns AP1 and AP2 may be greater than a width of the bit line BL in the first direction D1.

In FIG. 5, each of the first active pattern AP1 and the second active pattern AP2 may have the first surface S1 and the second surface S2 that are opposite to each other in the third direction D3. For example, first surfaces S1 of the first and second active patterns AP1 and AP2 may contact the polysilicon pattern 161 of the bit line BL. Unlike the drawings, if the polysilicon pattern 161 is omitted, the first surfaces S1 of the first and second active patterns AP1 and AP2 may contact the metal pattern 163.

Each of the first active pattern AP1 and the second active pattern AP2 may include a first side wall S3 and a second side wall S4 that are opposite to each other in the second direction D2. The second side wall S4 of the first active pattern AP1 may face the first side wall S3 of the second active pattern AP2.

As described below, the first side wall S3 of the first active pattern AP1 may be adjacent to the first back gate electrode BG1, and the second side wall S4 of the first active pattern AP1 may be adjacent to the first word line WL1. The second side wall S4 of the second active pattern AP2 may be adjacent to the second back gate electrode BG2, and the first side wall S3 of the second active pattern AP2 may be adjacent to the second word line WL2.

As an example, each of the first active pattern AP1 and the second active pattern AP2 may include a first dopant region SDR1 adjacent to the bit line BL and a second dopant region SDR2 adjacent to a contact pattern BC. Each of the first active pattern AP1 and the second active pattern AP2 may include a channel region between the first dopant region SDR1 and the second dopant region SDR2. The first and second dopant regions SDR1 and SDR2 are regions doped with a dopant within the first and second active patterns AP1 and AP2. Impurity concentrations within the first and second dopant regions SDR1 and SDR2 may be greater than impurity concentrations of the channel regions of the first and second active patterns AP1 and AP2.

Unlike the drawings, each of the first active pattern AP1 and the second active pattern AP2 may not include at least one of the first dopant region SDR1 and the second dopant region SDR2.

During an operation of the semiconductor memory, the channel regions of the first and second active patterns AP1 and AP2 may be controlled by the first and second word lines WL1 and WL2 and the first and second back gate electrodes BG1 and BG2. Because each of the first and second active patterns AP1 and AP2 is made of a monocrystalline semiconductor material, a leakage current characteristic of the semiconductor memory device may be improved.

The semiconductor memory device according to some example embodiments may further include an insertion semiconductor pattern disposed between the first active pattern AP1 and the metal pattern 163 and between the second active pattern AP2 and the metal pattern 163.

The insertion semiconductor pattern may include a different semiconductor material than the first and second active patterns AP1 and AP2. When each of the first and second active patterns AP1 and AP2 includes silicon, the insertion semiconductor pattern may include silicon germanium, but example embodiments of the present disclosure are not limited thereto. A floating body effect may be improved by inserting the insertion semiconductor pattern. The insertion semiconductor pattern between the first active pattern AP1 and the metal pattern 163 may be spaced apart from the insertion semiconductor pattern between the second active pattern AP2 and the metal pattern 163 in the second direction D2.

The first and second back gate electrodes BG1 and BG2 may be disposed above the bit line BL and bit line shielding structure 171, SL, and 175. The first and second back gate electrodes BG1 and BG2 may be spaced apart from each other in the second direction D2. The first and second back gate electrodes BG1 and BG2 may be spaced apart at regular intervals. The first and second back gate electrodes BG1 and BG2 may extend across the bit line BL in the first direction D1.

The first and second back gate electrodes BG1 and BG2 may be adjacent to the first side wall S3 of the first active pattern AP1 and may be adjacent to the second side wall S4 of the second active pattern AP2, respectively. The first and second back gate electrodes BG1 and BG2 may be disposed outside a pair of the first and second active patterns AP1 and AP2 that are alternately disposed in the second direction D2. Additionally, the first and second back gate electrodes BG1 and BG2 may be disposed between two pairs of the first and second active patterns AP1 and AP2 that are adjacent to each other in the second direction D2.

In other words, based on the pair of the first and second active patterns AP1 and AP2, the first back gate electrode BG1 may be adjacent to the first side wall S3 of the first active pattern AP1 and the second back gate electrode BG2 may be adjacent to the second side wall S4 of the second active pattern AP2. Additionally, the first back gate electrode BG1 may be adjacent to the first side wall S3 of the first active pattern AP1 belonging to one pair, and may be adjacent to the second side wall S4 of the second active pattern AP2 belonging to another pair. That is, the first back gate electrode BG1 may be disposed between the first active pattern AP1 belonging to the one pair and the second active pattern AP2 belonging to the other pair. The second back gate electrode BG2 may be adjacent to the second side wall S4 of the second active pattern AP2 belonging to one pair, and may be adjacent to the first side wall S3 of the first active pattern AP1 belonging to another pair. That is, the second back gate electrode BG2 may be disposed between the second active pattern AP2 belonging to the one pair and the first active pattern AP1 belonging to the other pair.

For example, the second back gate electrode BG2, the second active pattern AP2, the second word line WL2, the word line shielding structure GSS, the first word line WL1, the first active pattern AP1, the first back gate electrode BG1, the second active pattern AP2, the second word line WL2, the word line shielding structure GSS, the first word line WL1, and the first active pattern AP1 may be sequentially disposed in the second direction D2, and this disposition may be repeated in the second direction D2.

Each of the first and second back gate electrodes BG1 and BG2 may have a first surface BG_S1 and a second surface BG_S2 that are opposite to each other in the third direction D3. The first surface BG_S1 of each of the first and second back gate electrodes BG1 and BG2 is closer to the bit line BL than the second surface BG_S2 of each of the first and second back gate electrodes BG1 and BG2. In other words, the first surface BG_S1 of each of the first and second back gate electrodes BG1 and BG2 may be a lower end portion, and the second surface BG_S2 of each of the first and second back gate electrodes BG1 and BG2 may be an upper end portion.

A length H_BG of each of the first and second back gate electrodes BG1 and BG2 in the third direction D3 may be smaller than a length of each of the first and second active patterns AP1 and AP2 in the third direction D3. The length H_BG of each of the first and second back gate electrodes BG1 and BG2 in the third direction D3 may be equal to or smaller than a length of each of the first and second word lines WL1 and WL2 in the third direction D3. Additionally, the length H_BG of each of the first and second back gate electrodes BG1 and BG2 in the third direction D3 may be equal to or smaller than a length of a word line shielding conductive pattern SS in the third direction D3 described below.

Each of the first and second back gate electrodes BG1 and BG2 may include a conductive material, and for example, each of the first and second back gate electrodes BG1 and BG2 may include doped polysilicon, conductive metal nitride, conductive metal silicon nitride, metal carbonitride, conductive metal silicide, conductive metal oxide, a two-dimensional material, a metal, or a combination thereof.

When the semiconductor memory device operates, a voltage may be applied to the first and second back gate electrodes BG1 and BG2, so that a threshold voltage of the vertical channel transistor may be adjusted. The leakage current characteristic may be mitigated or prevented from being deteriorated by adjusting the threshold voltage of the vertical channel transistor.

A back-gate separation pattern (or a back-gate isolation pattern) 111 may be disposed between the first active pattern AP1 and the second active pattern AP2 adjacent in the second direction D2. The back-gate separation pattern 111 may extend in the first direction D1 in parallel with the first and second back gate electrodes BG1 and BG2. The back-gate separation pattern 111 may be disposed on the second surface BG_S2 of each of the first and second back gate electrodes BG1 and BG2.

For example, the back-gate separation pattern 111 may include a silicon oxide film, a silicon oxynitride film, or a silicon nitride film. The back-gate separation pattern 111 may be formed at the same level as a first gate capping pattern 143 that will be described below. Here, that the back-gate separation pattern 111 is formed at the same level as the first gate capping pattern 143 means that the back-gate separation pattern 111 is formed by the same manufacturing process as the first gate capping pattern 143. The back-gate separation pattern 111 may be formed of the same material as the first gate capping pattern 143.

A back-gate insulating pattern 113 may be disposed between the first back gate electrode BG1 and the first active pattern AP1 and between the second back gate electrode BG2 and the second active pattern AP2. The back-gate insulating pattern 113 may be disposed between the back-gate separation pattern 111 and the first active pattern AP1 and between the back-gate separation pattern 111 and the second active pattern AP2. For example, the back-gate insulating pattern 113 may include a silicon oxide film, a silicon oxynitride film, a high dielectric constant insulating film having a higher dielectric constant than the silicon oxide film, or a combination thereof.

A back-gate capping pattern 115 may be disposed between the bit line BL and the first and second back gate electrodes BG1 and BG2. The back-gate capping pattern 115 may be disposed between the first active pattern AP1 and the second active pattern AP2 adjacent in the second direction D2. The back-gate capping pattern 115 may extend in the first direction D1 in parallel with the first and second back gate electrodes BG1 and BG2. The back-gate capping pattern 115 may be disposed on the first surface BG_S1 of each of the first and second back gate electrodes BG1 and BG2. A thickness of the back-gate capping pattern 115 between the bit lines BL may be different from a thickness of the back-gate capping pattern 115 on the bit line BL. The back-gate capping pattern 115 may be made of an insulating material. For example, the back-gate capping pattern 115 may include a silicon oxide film, a silicon oxynitride film, a silicon nitride film, or a combination thereof.

The first word line WL1 and the second word line WL2 may be disposed above the bit line BL and the bit line shielding structure 171, SL, and 175. Each of the first word line WL1 and the second word line WL2 may extend in the first direction D1. The first word line WL1 and the second word line WL2 may be alternately disposed in the second direction D2.

The first and second word lines WL1 and WL2 may be disposed between the first active pattern AP1 and the second active pattern AP2, the first word line WL1 may be disposed above the second side wall S4 of the first active pattern AP1, and the second word line WL2 may be disposed above the first side wall S3 of the second active pattern AP2.

The first word line WL1 corresponds to the first back gate electrode BG1 with the first active pattern AP1 interposed therebetween. That is, the first active pattern AP1 is disposed between the first word line WL1 and the first back gate electrode BG1. In other words, the first word line WL1 is disposed adjacent to the second side wall S4 of the first active pattern AP1, and the first back gate electrode BG1 is disposed adjacent to the first side wall S3 of the first active pattern AP1.

The second word line WL2 is disposed to correspond to the second back gate electrode BG2 with the second active pattern AP2 interposed therebetween. That is, the second active pattern AP2 is disposed between the second word line WL2 and the second back gate electrode BG2. In other words, the second word line WL2 is disposed adjacent to the first side wall S3 of the second active pattern AP2, and the second back gate electrode BG2 is disposed adjacent to the second side wall S4 of the second active pattern AP2.

For example, the second back gate electrode BG2, the second active pattern AP2, the second word line WL2, the word line shielding structure GSS, the first word line WL1, the first active pattern AP1, the first back gate electrode BG1, the second active pattern AP2, the second word line WL2, the word line shielding structure GSS, the first word line WL1, and the first active pattern AP1 may be sequentially disposed in the second direction D2, and this disposition may be repeated in the second direction D2.

The first word line WL1 and the second word line WL2 may be spaced apart from the bit line BL and the contact pattern BC in the third direction D3. That is, the first word line WL1 and the second word line WL2 may be disposed between the bit line BL and the contact pattern BC.

Each of the first word line WL1 and the second word line WL2 may have a width in the second direction D2. A width of the first word line WL1 and a width of the second word line WL2 above the bit line BL may be different from the width of the first word line WL1 and the width of the second word line WL2 above the bit line shielding structure 171, SL, and 175.

For example, each of the first word line WL1 and the second word line WL2 may include a first portion WLa and a second portion WLb. A width of the first portion WLa of each of the first and second word lines WL1 and WL2 in the second direction D2 may be smaller than that of the second portion WLb of each of the first and second word lines WL1 and WL2 in the second direction D2. As an example, the first portion WLa of each of the first and second word lines WL1 and WL2 may be disposed above the bit line BL. The second portion WLb of each of the first and second word lines WL1 and WL2 may be disposed above the bit line shielding structure 171, SL, and 175.

The first portion WLa and the second portion WLb of each of the first and second word lines WL1 and WL2 may be alternately disposed along the first direction D1. In the first word line WL1, each of the first active patterns AP1 may be disposed between second portions WLb of adjacent first word lines WL1 in the first direction D1. In the second word line WL2, each of the second active patterns AP2 may be disposed between second portions WLb of adjacent second word lines WL2 in the first direction D1.

Each of the first word line WL1 and the second word line WL2 may have a first surface WL_S1 and a second surface WL_S2 that are opposite to each other in the third direction D3. The first surface WL_S1 of each of the first and second word lines WL1 and WL2 is closer to the bit line BL than the second surface WL_S2 of each of the first and second word lines WL1 and WL2. In other words, the first surface WL_S1 of each of the first and second word lines WL1 and WL2 may be a lower end portion, and the second surface WL_S2 of each of the first and second word lines WL1 and WL2 may be an upper end portion.

The first word line WL1 will be described. As an example, a length of the first word line WL1 in the third direction D3 may be the same as the length of each of the first and second back gate electrodes BG1 and BG2 in the third direction D3. As another example, the length of the first word line WL1 in the third direction D3 may be greater than the length of each of the first and second back gate electrodes BG1 and BG2 in the third direction D3. As another example, the length of the first word line WL1 in the third direction D3 may be less than the length of each of the first and second back gate electrodes BG1 and BG2 in the third direction D3.

For example, a height of the first surface WL_S1 of the first word line WL1 based on the bit line BL may be the same as a height of the first surface BG_S1 of the back gate electrode BG based on the bit line BL. As another example, the height of the first surface WL_S1 of the first word line WL1 may be greater than the height of the first surface BG_S1 of the back gate electrode BG. As another example, the height of the first surface WL_S1 of the first word line WL1 may be less than the height of the first surface BG_S1 of the back gate electrode BG.

Additionally, as an example, a height of the second surface WL_S2 of the first word line WL1 based on the bit line BL may be the same as a height of the second surface BG_S2 of the back gate electrode BG based on the bit line BL. As another example, the height of the second surface WL_S2 of the first word line WL1 may be greater than the height of the second surface BG_S2 of the back gate electrode BG. As another example, the height of the second surface WL_S2 of the first word line WL1 may be less than the height of the second surface BG_S2 of the back gate electrode BG.

Each of the first and second words lines WL1 and WL2 may include a conductive material, and for example, each of the first and second words lines WL1 and WL2 may include doped polysilicon, conductive metal nitride, conductive metal silicon nitride, metal carbonitride, conductive metal silicide, conductive metal oxide, a two-dimensional material, a metal, or a combination thereof.

In some example embodiments, the first surface WL_S1 of each of the first and second word lines WL1 and WL2 may have various shapes. As an example, the first surface WL_S1 of each of the first and second word lines WL1 and WL2 may be concavely rounded. Each of the first and second word lines WL1 and WL2 may have a spacer shape. In other words, the first surface WL_S1 of each of the first and second word lines WL1 and WL2 may be convexly rounded.

Additionally, on a cross-section cut in the second direction D2, the second surface WL_S2 of each of the first and second word lines WL1 and WL2 may have a concave curved surface or may have a flat surface. Additionally, the first surface BG_S1 of each of the first and second back gate electrodes BG1 and BG2 may have a concave curved surface or may have a flat surface. Additionally, the second surface BG_S2 of each of the first and second back gate electrodes BG1 and BG2 may have a concave curved surface or may have a flat surface. Example embodiments of the present disclosure are not limited thereto, and one of the first surface BG_S1 of each of the first and second back gate electrodes BG1 and BG2 and the second surface BG_S2 of each of the first and second back gate electrodes BG1 and BG2 may be flat.

A gate insulating pattern GOX may be disposed between the first word line WL1 and the first active pattern AP1 and between the second word line WL2 and the second active pattern AP2. Gate insulating patterns GOX may extend in the first direction D1 parallel to the first and second word lines WL1 and WL2.

The gate insulating pattern GOX may include a silicon oxide film, a silicon oxynitride film, a high dielectric constant insulating film having a higher dielectric constant than the silicon oxide film, or a combination thereof.

The gate insulating pattern GOX may extend along the second side wall S4 of the first active pattern AP1 and the first side wall S3 of the second active pattern AP2. In the semiconductor memory device according to some example embodiments, from a cross-sectional perspective, the gate insulating pattern GOX between the first active pattern AP1 and the first word line WL1 may be separated from the gate insulating pattern GOX between the second active pattern AP2 and the second word line WL2.

The first gate capping pattern 143 may be disposed between the first word line WL1 and the contact pattern BC and between the second word line WL2 and the contact pattern BC. The first gate capping pattern 143 may cover the second surface WL_S2 of each of the first and second word lines WL1 and WL2.

Additionally, a second gate capping pattern 153 may be disposed between the first word line WL1 and the bit line BL and between the second word line WL2 and the bit line BL. The second gate capping pattern 153 may cover the first surface WL_S1 of each of the first and second word lines WL1 and WL2.

The word line shielding structure GSS may be disposed on the bit line BL. The word line shielding structure GSS may be disposed between the bit line BL and the contact pattern BC in the third direction D3. The word line shielding structure GSS may contact the bit line BL.

The word line shielding structure GSS may be disposed between the first word line WL1 and the second word line WL2 that are adjacent to each other in the second direction D2. That is, the first word line WL1 and the second word line WL2 may be separated by the word line shielding structure GSS. The word line shielding structure GSS may extend between the first word line WL1 and the second word line WL2 in the first direction D1 and the third direction D3.

The first word line WL1 may be disposed between the word line shielding structure GSS and the first active pattern AP1. The second word line WL2 may be disposed between the word line shielding structure GSS and the second active pattern AP2.

The word line shielding structure GSS may include the word line shielding conductive pattern SS and word line shielding insulating films 154 and 155.

The word line shielding conductive pattern SS may be disposed above the bit line BL in the third direction D3, may be disposed between the first and second word lines WL1 and WL2 that are adjacent to each other in the second direction D2, and may extend in the first direction D1.

The word line shielding conductive pattern SS may have a first side surface SS_S3 and a second side surface SS_S4 that are opposite to each other in the second direction D2. A second side surface WL_S4 of the first word line WL1 is disposed adjacent to the first side surface SS_S3 of the word line shielding conductive pattern SS, and a first side surface WL_S3 of the second word line WL2 is disposed adjacent to the second side surface SS_S4 of the word line shielding conductive pattern SS.

The word line shielding conductive pattern SS may have a first surface SS_S1 and a second surface SS_S2 that are opposite to each other in the third direction D3. The first surface SS_S1 of the word line shielding conductive pattern SS is closer to the bit line BL than the second surface SS_S2 of the word line shielding conductive pattern SS. That is, the first surface SS_S1 of the word line shielding conductive pattern SS may be a lower end portion of the word line shielding conductive pattern SS, and the second surface SS_S2 of the word line shielding conductive pattern SS may be an upper end portion of the word line shielding conductive pattern SS.

As an example, a length H_SS of the word line shielding conductive pattern SS in the third direction D3 may be greater than a length H_WL of each of the first and second word lines WL1 and WL2 in the third direction D3. That is, the word line shielding conductive pattern SS may extend in the third direction D3, and may overlap the first and second word lines WL1 and WL2 in the second direction D2. Accordingly, the word line shielding structure GSS may further reduce coupling between the first and second word lines WL1 and WL2.

Additionally, the length H_SS of the word line shielding conductive pattern SS in the third direction D3 may be greater than the length H_BG of each of the first and second back gate electrodes BG1 and BG2 in the third direction D3. That is, the word line shielding conductive pattern SS may extend in the third direction D3, and may overlap the first and second back gate electrodes BG1 and BG2 in the second direction D2.

As an example, a height of the first surface SS_S1 of the word line shielding conductive pattern SS based on the bit line BL may be the same as a height of the first surface WL_S1 of each of the first and second word lines WL1 and WL2 based on the bit line BL. As another example, the height of the first surface SS_S1 of the word line shielding conductive pattern SS may be greater than the height of the first surface WL_S1 of each of the first and second word lines WL1 and WL2. As another example, the height of the first surface SS_S1 of the word line shielding conductive pattern SS may be less than the height of the first surface WL_S1 of each of the first and second word lines WL1 and WL2.

In addition, as an example, a height of the second surface SS_S2 of the word line shielding conductive pattern SS based on the bit line BL may be the same as a height of the second surface WL_S2 of each of the first and second word lines WL1 and WL2 based on the bit line BL. As another example, the height of the second surface SS_S2 of the word line shielding conductive pattern SS may be greater than the height of the second surface WL_S2 of each of the first and second word lines WL1 and WL2. As another example, the height of the second surface SS_S2 of the word line shielding conductive pattern SS may be lower than the height of the second surface WL_S2 of each of the first and second word lines WL1 and WL2.

In addition, as an example, a height of the first surface SS_S1 of the word line shielding conductive pattern SS based on the bit line BL is the same as a height of the first surface BG_S1 of each of the first and second back gate electrodes BG1 and BG2 based on the bit line BL. As another example, the height of the first surface SS_S1 of the word line shielding conductive pattern SS may be greater than the height of the first surface BG_S1 of each of the first and second back gate electrodes BG1 and BG2. As another example, the height of the first surface SS_S1 of the word line shielding conductive pattern SS may be less than the height of the first surface BG_S1 of each of the first and second back gate electrodes BG1 and BG2.

In addition, as an example, a height of the second surface SS_S2 of the word line shielding conductive pattern SS based on the bit line BL may be the same as a height of the second surface BG_S2 of each of the first and second back gate electrodes BG1 and BG2 based on the bit line BL. As another example, the height of the second surface SS_S2 of the word line shielding conductive pattern SS may be greater than the height of the second surface BG_S2 of each of the first and second back gate electrodes BG1 and BG2. As another example, the height of the second surface SS_S2 of the word line shielding conductive pattern SS may be less than the height of the second surface BG_S2 of each of the first and second back gate electrodes BG1 and BG2.

The word line shielding conductive pattern SS may include a conductive material, and for example, the word line shielding conductive pattern SS may include at least one of conductive metal nitride, conductive metal silicon nitride, metal carbonitride, conductive metal silicide, conductive metal oxide, a two-dimensional material, and a metal.

The word line shielding insulating films 154 and 155 may include the word line shielding insulating liner 155 and the word line shielding insulating capping film 154.

The word line shielding insulating liner 155 may be disposed between the word line shielding conductive pattern SS and the first and second word lines WL1 and WL2. In other words, the word line shielding insulating liner 155 may be disposed on the second surface SS_S2, the first side surface SS_S3, and the second side surface SS_S4 of the word line shielding conductive pattern SS. That is, the word line shielding insulating liner 155 may cover an upper surface and a side surface of the word line shielding conductive pattern SS.

The word line shielding insulating capping film 154 may be disposed between the word line shielding conductive pattern SS and the bit line BL in the third direction D3. That is, the word line shielding insulating capping film 154 may cover the first surface SS_S1 of the word line shielding conductive pattern SS. The word line shielding insulating capping film 154 may be disposed between the word line shielding insulating liner 155 in the second direction D2. Accordingly, the word line shielding insulating films 154 and 155 may surround the word line shielding conductive pattern SS, and the word line shielding conductive pattern SS may be disposed inside the word line shielding Insulating films 154 and 155.

Each of the word line shielding insulating liner 155 and the word line shielding insulating capping film 154 may be made of an insulating material. For example, the insulating material included in each of the word line shielding insulating liner 155 and the word line shielding insulating capping film 154 may include a silicon oxide film, a silicon oxynitride film, a silicon nitride film, or a combination thereof. If the word line shielding insulating liner 155 and the word line shielding insulating capping film 154 include the same material, a boundary between the word line shielding insulating liner 155 and the word line shielding insulating capping film 154 may not be substantially distinguished.

The semiconductor memory device according to one aspect may improve a degree of integration by reducing the number of the first and second word lines WL1 and WL2 by the first and second back gate electrodes BG1 and BG2. In addition, the semiconductor memory device may further reduce an interval between the first and second word lines WL1 and WL2 to improve the degree of integration by controlling coupling between the first and second word lines WL1 and WL2 through the word line shielding structure GSS.

For example, an interval W_BWL between a pair of the first word line WL1 and the second word line WL2 that are adjacent to each other in the second direction D2 may be 10 nm or less, 9 nm or less, 8 nm or less, 7 nm or less, 6 nm or less, 5 nm or less, 4 nm or less, 3 nm or less, 1 nm or more, 2 nm or more, 3 nm or more, 4 nm or more, 5 nm or more, or 6 nm or more. Here, the interval W_BWL between the first word line WL1 and the second word line WL2 may be the shortest distance in the second direction D2 between the second side surface WL_S4 of the first word line WL1 and the first side surface WL_S3 of the second word line WL2 adjacent to each other.

In addition, for example, a width W_SS of the word line shielding conductive pattern SS in the second direction D2 may be 5 nm or less, 4 nm or less, 3 nm or less, 2 nm or less, 1 nm or less, 1 nm or more, 2 nm or more, 3 nm or more, or 4 nm or more. Here, the width W_SS of the word line shielding conductive pattern SS may be the shortest distance in the second direction D2 between the first side surface SS_S3 and the second side surface SS_S4 in any one word line shielding conductive pattern SS.

Additionally, a width W_155 of the word line shielding insulating liner 155 in the second direction D2 may be 5 nm or less, 4 nm or less, 3 nm or less, 2 nm or less, 1 nm or less, 1 nm or more, 2 nm or more, 3 nm or more, or 4 nm or more. Here, the width W_155 of the word line shielding insulating liner 155 may be the shortest distance in the second direction D2 between the first side surface SS_S3 of the word line shielding conductive pattern SS and the second side surface WL_S4 of the first word line WL1, or may be the shortest distance in the second direction D2 between the second side surface SS_S4 of the word line shielding conductive pattern SS and the first side surface WL_S3 of the second word line WL2. That is, the word line shielding insulating liner 155 may be conformally formed to have a constant thickness, and a distance of the word line shielding insulating liner 155 in the second direction D2 may mean a thickness of the word line shielding insulating liner 155.

Accordingly, for example, a width of the word line shielding structure GSS in the second direction D2 may be 10 nm or less, 9 nm or less, 8 nm or less, 7 nm or less, 6 nm or less, 5 nm or less, 4 nm or less, or 3 nm or less, 1 nm or more, 2 nm or more, 3 nm or more, 4 nm or more, 5 nm or more, or 6 nm or more. Here, the width of the word line shielding structure GSS may be substantially equal to the interval W_BWL between the first word line WL1 and the second word line WL2.

Each of contact patterns BC may penetrate a contact interlayer insulating film 231 and contact etching stop films (or contact etch stop films) 211 and 212. The contact patterns BC may be connected to the first and second active patterns AP1 and AP2, respectively. The contact pattern BC may be connected to a second surface S2 of each of the first and second active patterns AP1 and AP2. When the contact pattern BC is viewed in a plan view, the contact pattern BC may have various shapes such as a circular shape, an oval shape, a rectangular shape, a square shape, a rhombic shape, a hexagonal shape, and the like.

The contact pattern BC may include a conductive material, and for example, the contact pattern BC may include doped polysilicon, conductive metal nitride, conductive metal silicon nitride, metal carbonitride, conductive metal silicide, conductive metal oxide, a two-dimensional material, a metal, or a combination thereof.

The contact etching stop films 211 and 212 may include the lower contact etching stop film 211 and the upper contact etching stop film 212. The lower contact etching stop film 211 and the upper contact etching stop film 212 may be sequentially stacked on the first gate capping pattern 143 and the back-gate separation pattern 111. Unlike the drawings, the contact etching stop film may be a single film. Each of the contact interlayer insulating film 231, the lower contact etching stop film 211, and the upper contact etching stop film 212 may be made of an insulating material.

In some example embodiments, the lower contact etching stop film 211 and the upper contact etching stop film 212 may not be disposed on the first gate capping pattern 143 and the back-gate separation pattern 111. As an example, the contact pattern BC may be formed in an embossed manner. As an example, a contact film is formed on the first gate capping pattern 143, the back-gate separation pattern 111, and the second surface S2 of each of the first and second active patterns AP1 and AP2. Thereafter, the contact pattern BC may be formed by patterning the contact film. A contact separation pattern is formed between separated contact patterns BC. The contact separation pattern may be made of an insulating material. Additionally, the contact pattern BC may include a lower contact pattern and an upper contact pattern. The lower contact pattern contacts the first and second active patterns AP1 and AP2. The upper contact pattern is disposed on the lower contact pattern. A concentration of impurity included in the lower contact pattern may be greater than a concentration of impurity included in the upper contact pattern.

Each of landing pads LP may be disposed on the contact pattern BC. When the landing pad LP is viewed in a plan view, the landing pad LP may have various shapes such as a circular shape, an oval shape, a rectangular shape, a square shape, a rhombic shape, a hexagonal shape, and the like.

Each of pad separation insulating patterns 235 may be disposed between the landing pads LP. When the landing pads LP are viewed in a plan view, the landing pads LP may be disposed in a matrix form along the first direction D1 and the second direction D2. An upper surface of the landing pad LP may be substantially coplanar with an upper surface of the pad separation insulating pattern 235.

The landing pad LP may include a conductive material, and for example, the landing pad LP may include doped polysilicon, conductive metal nitride, conductive metal silicon nitride, metal carbonitride, conductive metal silicide, conductive metal oxide, a two-dimensional material, a metal, or a combination thereof.

The data storage patterns DSP may be respectively disposed on the landing pads LP. The data storage patterns DSP may be electrically connected to the first and second active patterns AP1 and AP2, respectively. As shown in FIG. 2, the data storage patterns DSP may be disposed in a matrix form along the first direction D1 and the second direction D2. The data storage patterns DSP may completely or partially overlap the landing pads LP in the third direction D3. The data storage patterns DSP may contact all or portions of upper surfaces of the landing pads LP.

As an example, the data storage patterns DSP may be a capacitor. The data storage patterns DSP may include a capacitor dielectric film 253 interposed between storage electrodes 251 and a plate electrode 255. In this case, the storage electrode 251 may contact the landing pad LP. When the storage electrode 251 is viewed in a plan view, the storage electrode 251 may have various shapes such as a circular shape, an oval shape, a rectangular shape, a square shape, a rhombic shape, a hexagonal shape, and the like. The data storage patterns DSP may completely or partially overlap the landing pads LP. The data storage patterns DSP may contact all or portions of upper surfaces of the landing pads LP. The storage electrodes 251 may penetrate an upper etching stop film 247. The upper etching stop film 247 may be made of an insulating material.

In some example embodiments, each of the data storage patterns DSP may be a variable resistance pattern that may be switched between two resistance states by an electrical pulse applied to a memory element. For example, the data storage pattern DSP may include a phase-change material changing a crystalline state according to an amount of electrical current, a perovskite compound, transition metal oxide, a magnetic material, a ferromagnetic material, or an antiferromagnetic material.

Although not shown in the drawings, a memory cell contact plug (PLG) connected to the plate electrode 255 may be disposed on the data storage patterns DSP.

Lower peripheral contact plugs LPLGa, LPLGb, and LPLGc penetrate an element separation film STI. The lower peripheral contact plugs LPLGa, LPLGb, and LPLGc may be connected to the metal pattern 163 disposed at an end portion of the bit line BL, an end portion of the bit line shielding conductive pattern SL, and the peripheral wire line 241 a.

Contact plug pads PLP may be disposed on the lower peripheral contact plugs LPLGa, LPLGb, and LPLGc. The pad separation insulating pattern 235 may be disposed between the contact plug pads PLP.

Upper peripheral contact plugs PPLG penetrate an upper interlayer insulating film 270 and the upper etching stop film 247. The upper peripheral contact plugs PPLG may be disposed on the contact plug pads PLP. The upper peripheral contact plug PPLG may be connected to the contact plug pad PLP.

Each of the lower peripheral contact plugs LPLGa, LPLGb, and LPLGc, each of the contact plug pads PLP, and each of the upper peripheral contact plugs PPLG may include a conductive material, and for example, each of the lower peripheral contact plugs LPLGa, LPLGb, and LPLGc, each of the contact plug pads PLP, and each of the upper peripheral contact plugs PPLG may include doped polysilicon, conductive metal nitride, conductive metal silicon nitride, metal carbonitride, conductive metal silicide, conductive metal oxide, a two-dimensional material, a metal, or a combination thereof.

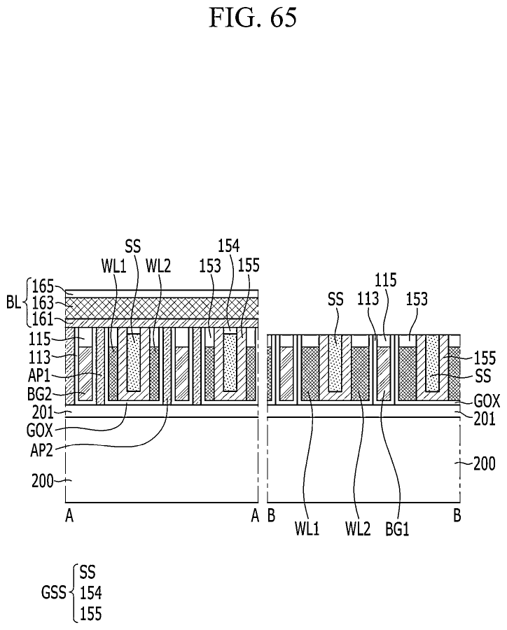

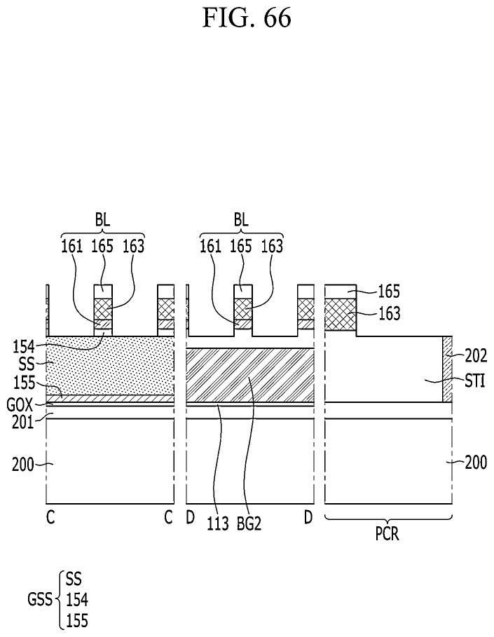

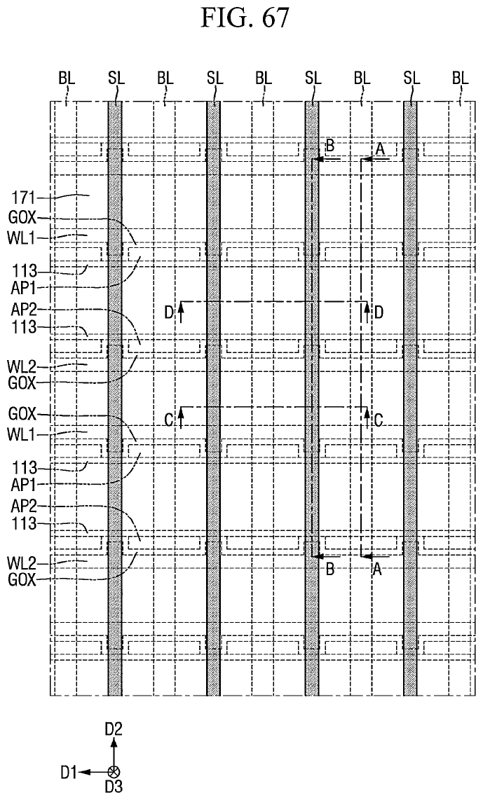

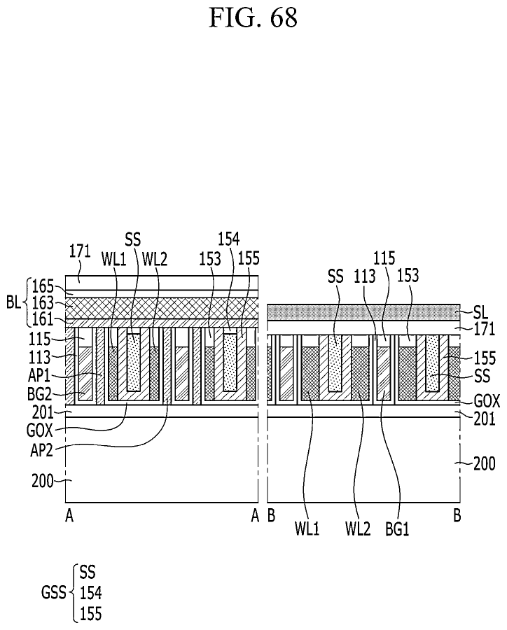

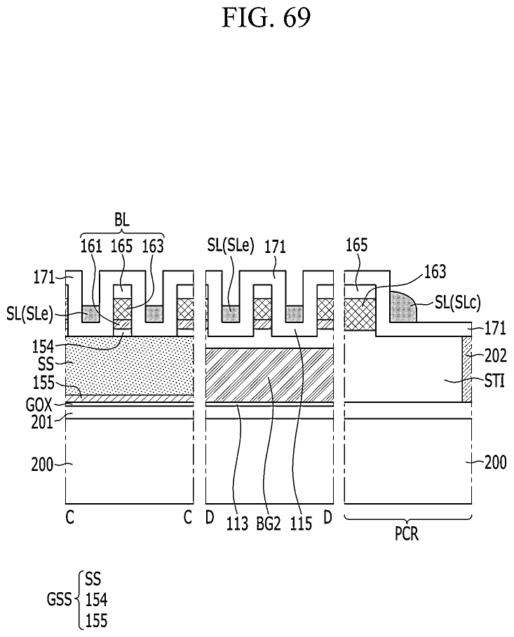

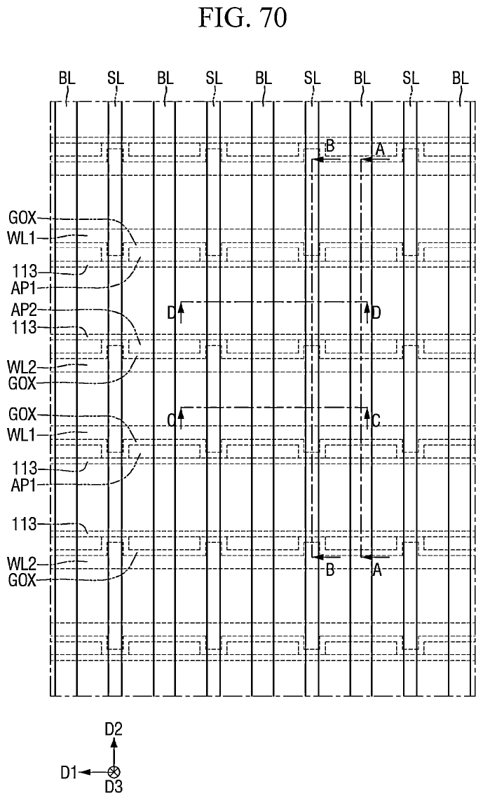

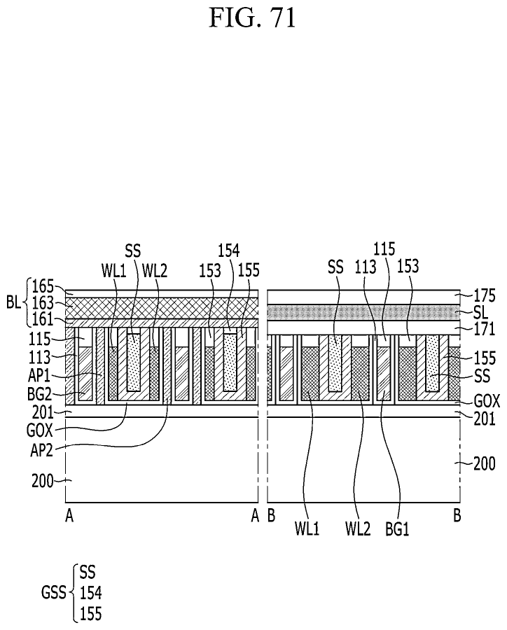

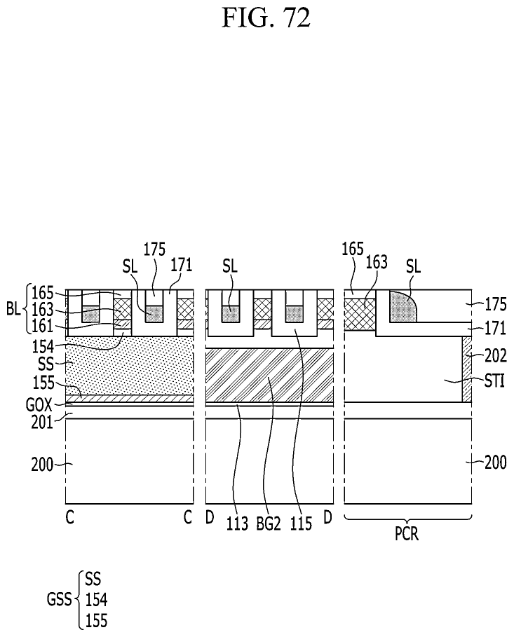

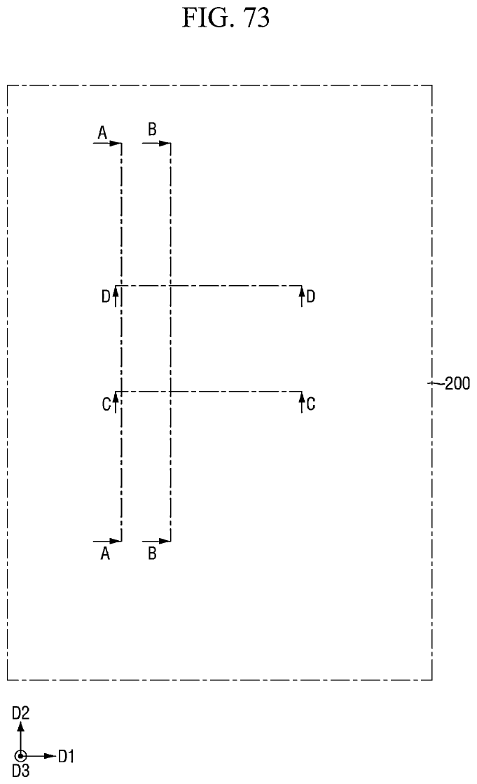

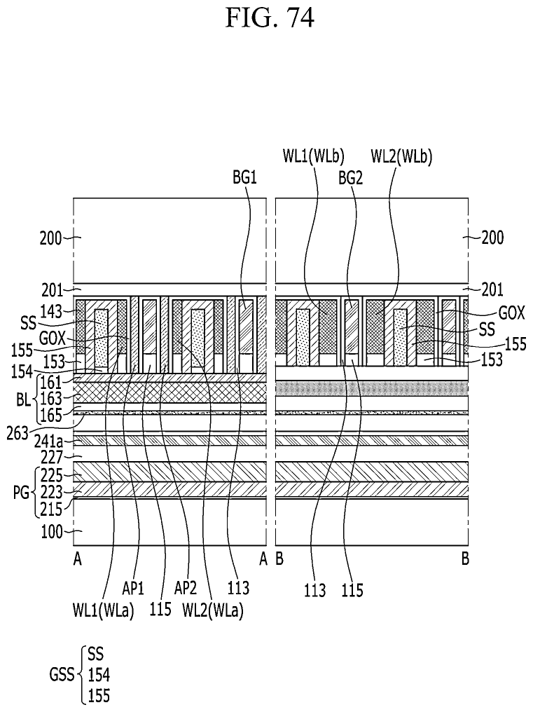

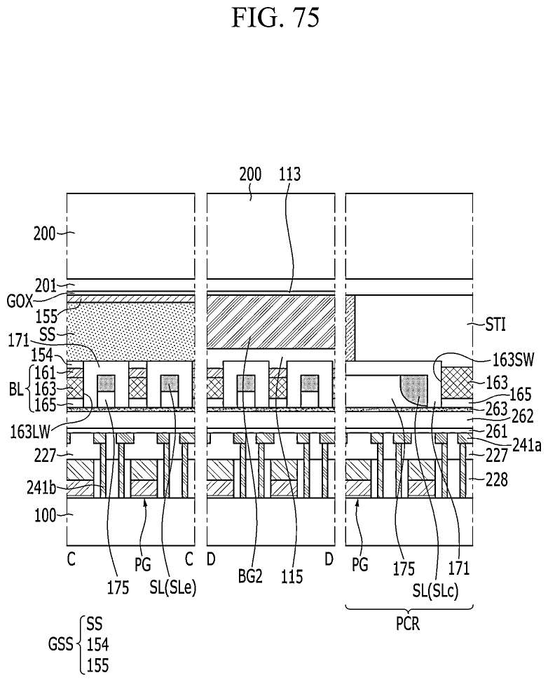

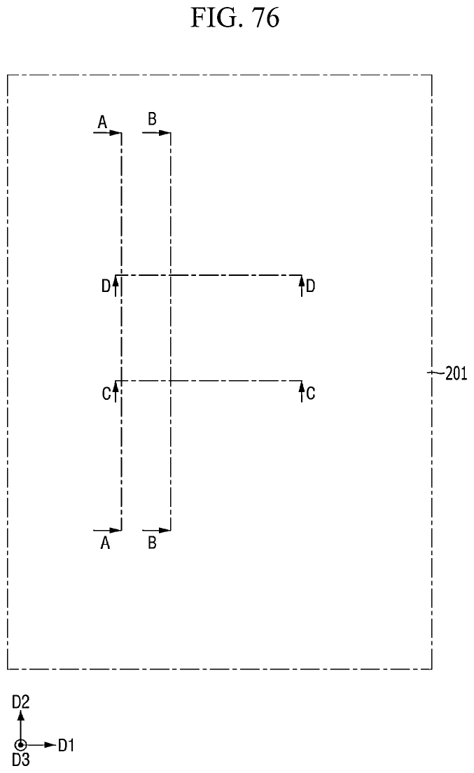

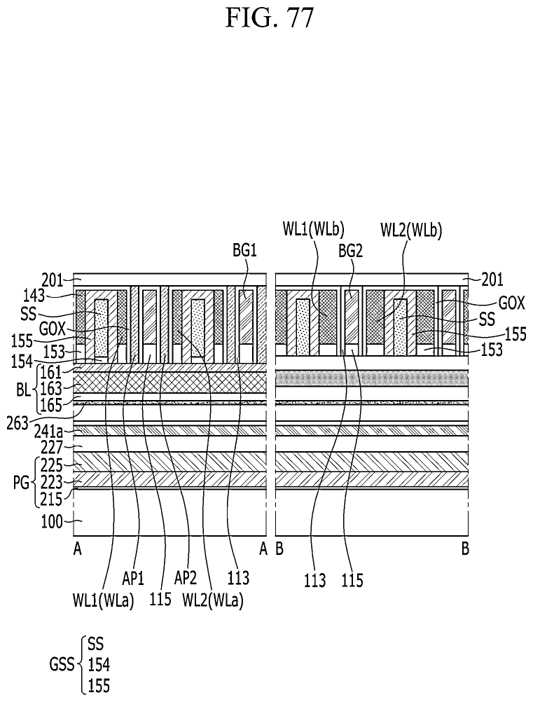

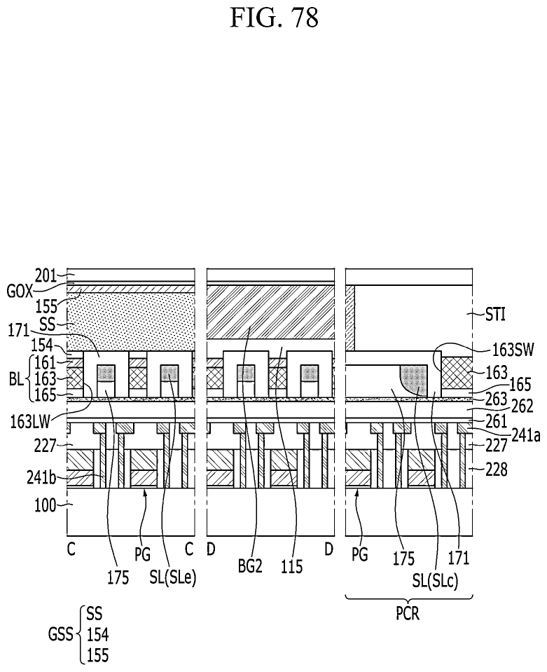

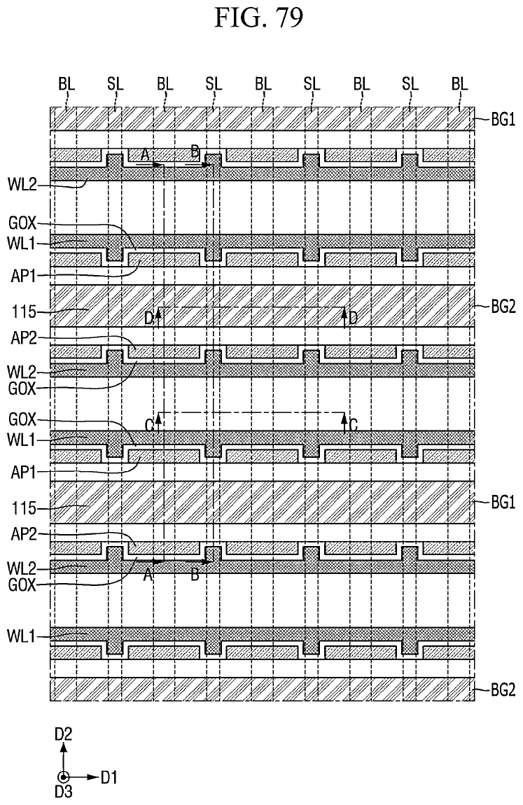

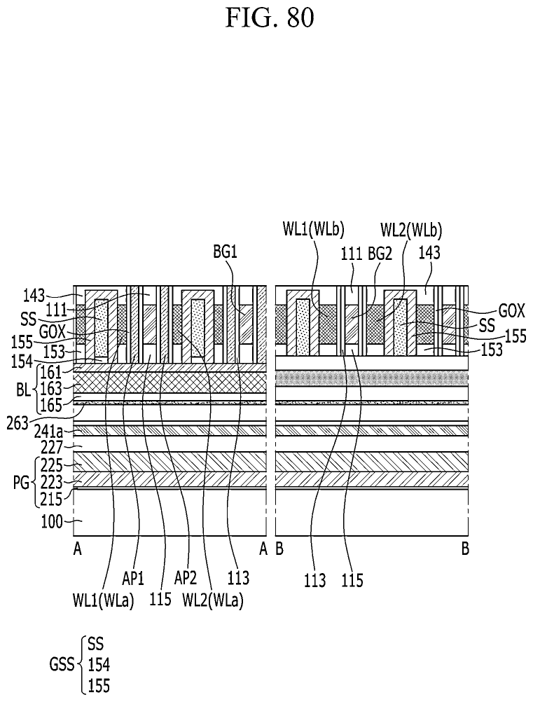

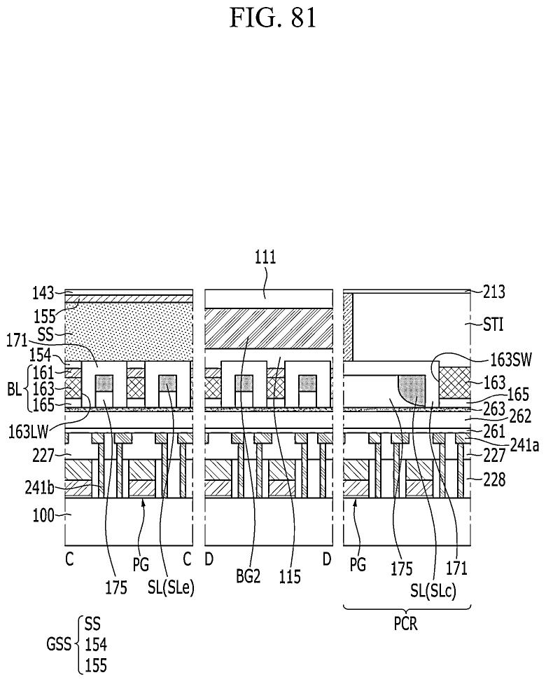

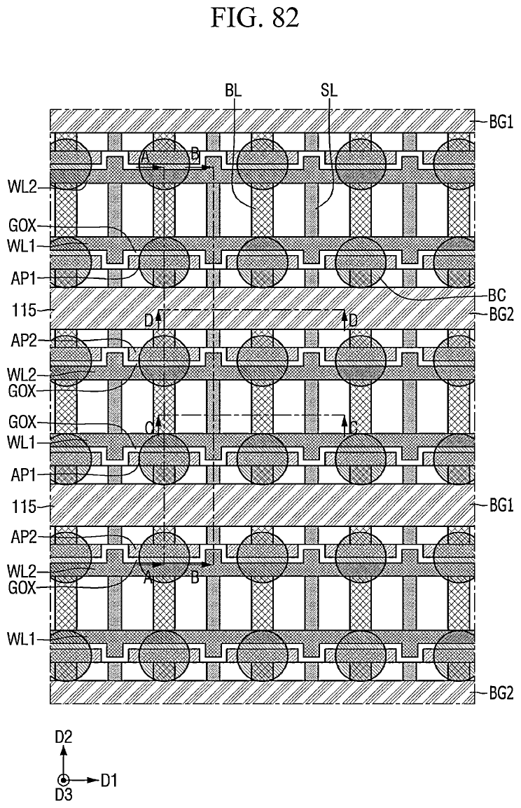

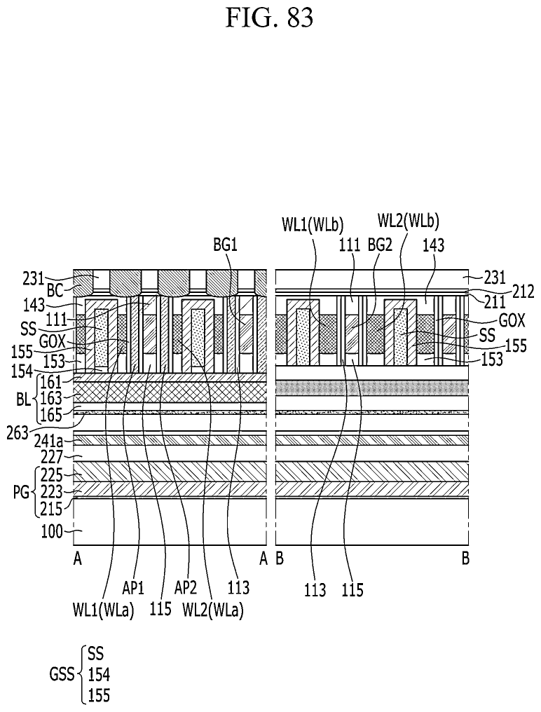

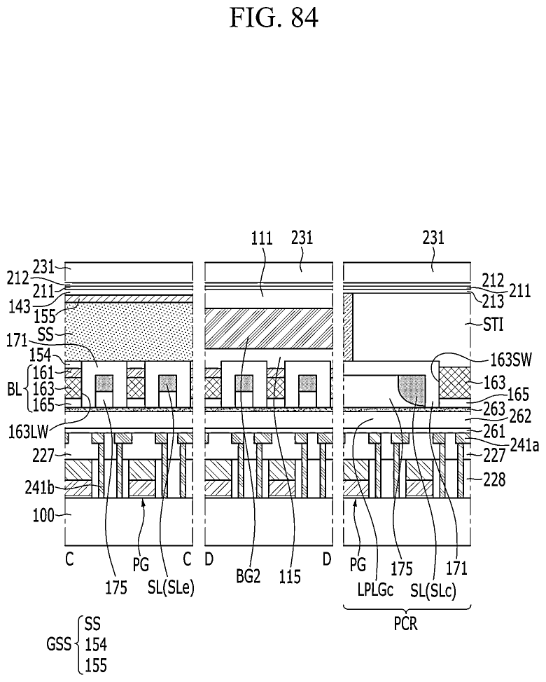

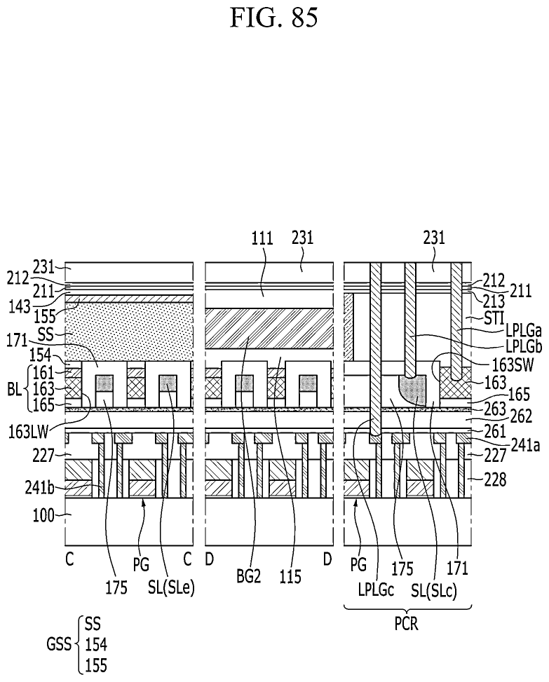

FIGS. 7 to 85 are views for describing a method for manufacturing the semiconductor memory device according to an example embodiment.

For reference, a cutting line and a coordinate system shown in FIGS. 10 to 72 are a cutting line and a coordinate system obtained by inverting a cutting line and a coordinate system of FIG. 2 in the first direction D1.

Referring to FIGS. 7 to 9, the peripheral gate structure PG may be formed on the substrate 100.

The peripheral wire line 241 a and the peripheral contact plug 241b may be formed above or on the substrate 100. The first peripheral upper insulating film 261 and the second peripheral upper insulating film 262 may be sequentially formed above or on the peripheral wire line 241a and the peripheral contact plug 241b. The bonding insulating film 263 may be formed on the second peripheral upper insulating film 262.

Referring to FIGS. 10 to 12, a sub-substrate structure including a sub-substrate 200, a buried insulating layer 201, and an active layer 202 may be provided.

The buried insulating layer 201 and the active layer 202 may be provided above or on the sub-substrate 200. The sub-substrate 200, the buried insulating layer 201, and the active layer 202 may be a silicon-on-insulator (SOI) substrate.

The sub-substrate 200 may include the cell array region CAR and the peripheral circuit region PCR. For example, the sub-substrate 200 may be a silicon substrate, a germanium substrate, and/or a silicon-germanium substrate.

The buried insulating layer 201 may be buried oxide (BOX) formed by a separation by implanted oxygen (SIMOX) method or a bonding and layer transfer method. For example, the buried insulating layer 201 may be an insulating film formed by a chemical vapor deposition method. For example, the buried insulating layer 201 may include a silicon oxide film, a silicon nitride film, a silicon oxynitride film, and/or a low dielectric constant insulating film.

The active layer 202 may be a monocrystalline semiconductor film. For example, the active layer 202 may be a monocrystalline silicon substrate, a monocrystalline germanium substrate, and/or a monocrystalline silicon-germanium substrate. The active layer 202 may have a first surface and a second surface that are opposite to each other in the third direction D3, and the second surface of the active layer 202 may contact the buried insulating layer 201.

The element separation film STI may be formed within the active layer 202 of the peripheral circuit region PCR. The element separation film STI may be formed by patterning the active layer 202 of the peripheral circuit region PCR to form an element separation trench that exposes the buried insulating layer 201 and then burying an insulating material within the element separation trench. An upper surface of the element separation film STI may be substantially coplanar with the first surface of the active layer 202.

Referring to FIGS. 13 to 15, a first mask pattern MP1 may be formed on the active layer 202.

The first mask pattern MP1 may include line-shaped openings extending along the first direction D1 in the cell array region CAR. The first mask pattern MP1 may include a first lower mask film 11 and a first upper mask film 12 sequentially stacked. The first upper mask film 12 may be made of a material that has an etching selectivity with respect to the first lower mask film 11. For example, the first lower mask film 11 may include silicon oxide, and the first upper mask film 12 may include silicon nitride, but example embodiments of the present disclosure are not limited thereto.

Subsequently, the active layer 202 of the cell array region CAR may be anisotropic-etched using the first mask pattern MP1 as an etching mask. Accordingly, back gate trenches BG_T extending in the first direction D1 may be formed in the active layer 202 of the cell array region CAR. The back gate trenches BG_T may expose the buried insulating layer 201, and may be spaced apart at regular intervals in the second direction D2.

Referring to FIGS. 16 to 18, the back-gate insulating pattern 113 and the first and second back gate electrodes BG1 and BG2 may be formed within the back gate trench BG_T.

More specifically, the back-gate insulating pattern 113 may be formed along a side wall and a bottom surface of the back gate trench BG_T and an upper surface of the first mask pattern MP1. A back-gate conductive film may be formed on the back-gate insulating pattern 113. The back-gate conductive film may fill the back gate trench BG_T. Next, the back-gate conductive film may be isotropically etched so that the first and second back gate electrodes BG1 and BG2 extending in the first direction D1 are formed. The first and second back gate electrodes BG1 and BG2 may fill a portion of the back gate trench BG_T.

On the other hand, according to some example embodiments, before the back-gate insulating pattern 113 is formed, a gas-phase doping (GPD) process or a plasma doping (PLAD) process may be performed. Through the above-described process, an impurity may be doped into the active layer 202 exposed by the back gate trench BG_T.

Referring to FIGS. 19 to 21, each of back-gate capping patterns 115 may be formed on the first and second back gate electrodes BG1 and BG2.

The back-gate capping pattern 115 may fill the remainder of the back gate trench BG_T. If the back-gate capping pattern 115 and the back-gate insulating pattern 113 are made of the same material (e.g., silicon oxide), the back-gate insulating pattern 113 on the upper surface of the first mask pattern MP1 may be removed while the back-gate capping pattern 115 is formed.

On the other hand, before the back-gate capping patterns 115 are formed, a gas-phase doping (GPD) process or a plasma doping (PLAD) process may be performed. Through this, impurities may be doped into the active layer 202 through the back gate trench BG_T in which the first and second back gate electrodes BG1 and BG2 are formed.

After the back-gate capping patterns 115 are formed, the first upper mask film 12 may be removed. The back-gate capping patterns 115 may have a shape that protrudes above an upper surface of the first lower mask film 11.

Referring to FIGS. 22 to 24, a spacer film 120 may be formed along an upper surface of the first lower mask film 11, side walls of the back-gate insulation patterns 113, and upper surfaces of the back-gate capping patterns 115. The spacer film 120 may be formed to have a uniform thickness. Widths of active patterns of vertical channel transistors may be determined depending on a deposition thickness of the spacer film 120. The spacer film 120 may be made of an insulating material. For example, the spacer film 120 may include silicon oxide, silicon oxynitride, silicon nitride, silicon carbide (SiC), silicon carbon nitride (SiCN), a combination thereof, or the like.

Subsequently, a peripheral mask pattern 20 that exposes the cell array region CAR may be formed on the spacer film 120 of the peripheral circuit region PCR.

Referring to FIGS. 25 to 27, a pair of spacer patterns 121 may be formed on a side wall of the back-gate insulating pattern 113 by performing an anisotropic etching process on the spacer film 120.

An anisotropic etching process may be performed on the active layer 202 using the spacer pattern 121 as an etching mask. Through this, a pair of pre-active patterns PAP separated from each other may be formed at both sides of each back-gate insulating pattern 113. The buried insulating layer 201 may be exposed by forming the pre-active patterns PAP.

Each of the pre-active patterns PAP may have a line shape extending in the first direction D1 parallel to each of the first and second back gate electrodes BG1 and BG2. A word line trench WL_T may be formed between the pre-active patterns PAP adjacent to each other in the second direction D2.

After the spacer pattern 121 is formed, the peripheral mask pattern 20 may be removed. A portion of the spacer film 120 may remain on the first lower mask film 11 of the peripheral circuit region PCR.

Referring to FIGS. 28 to 30, an etching stop film 31 may be formed along a side wall and a bottom surface of the word line trench WL_T.

A sacrificial film 33 that fills the word line trench WL_T in which the etching stop film 31 is formed may be formed. The sacrificial film 33 may fill the word line trench WL_T. The sacrificial film 33 may have a substantially flat upper surface.

The etching stop film 31 may be formed by depositing an insulating material (for example, silicon oxide), but example embodiments of the present disclosure are not limited thereto. The sacrificial film 33 may be formed of an insulating material with an etching selectivity with respect to the etching stop film 31. As an example, the sacrificial film 33 may be one of an insulating material and a silicon oxide film formed using spin-on-glass (SOG) technology, but example embodiments of the present disclosure are not limited thereto.

The etching stop film 31 and the sacrificial film 33 may be sequentially stacked on the spacer film 120 of the peripheral circuit region PCR.

Referring to FIGS. 31 to 33, a second mask pattern MP2 may be formed on the sacrificial film 33.

The second mask pattern MP2 may be formed of a material with an etching selectivity with respect to the sacrificial film 33. The second mask pattern MP2 may have a line shape that extends in the second direction D2. As another example, the second mask pattern MP2 may have a line shape extending in a diagonal direction with respect to the first direction D1 and the second direction D2.

Next, openings OP may be formed by etching the sacrificial film 33 using the second mask pattern MP2 as an etching mask. The openings OP may expose the etching stop film 31.

Referring to FIGS. 34 to 36, the etching stop film 31 exposed by the openings OP may be removed.

The openings OP may expose an upper surface of the buried insulating layer 201. Additionally, the openings OP may expose portions of the pre-active patterns PAP.

Next, the pre-active patterns PAP exposed by the openings OP may be etched so that the first active pattern AP1 and the second active pattern AP2 are formed at both sides of the first and second back gate electrodes BG1 and BG2. The first active patterns AP1 may be formed spaced apart from each other in the first direction D1 above the first side wall of each of the first and second back gate electrodes BG1 and BG2. The second active patterns AP2 may be formed spaced apart from each other in the first direction D1 above the second side wall of each of the first and second back gate electrodes BG1 and BG2. In another example, if the second mask pattern MP2 extends in the diagonal direction, the first and second active patterns AP1 and AP2 may be disposed to face each other in the diagonal direction. Because the first active pattern AP1 and the second active pattern AP2 are formed, the openings OP may expose a portion of the back-gate insulating pattern 113.

Referring to FIGS. 37 to 39, the sacrificial film 33 may be filled within the openings OP. The sacrificial film 33 that fills the opening OP may be the same material as the sacrificial film 33 that fills the word line trench WL_T of FIG. 51 and FIG. 52.

After the sacrificial film 33 is filled within the opening OP, the second mask pattern MP2 may be removed. A planarization process may be performed on the sacrificial film 33 and the etching stop film 31 so that an upper surface of the back-gate capping pattern 115 is exposed. Next, the spacer pattern 121 and the first lower mask film 11 may be removed. Through this, the first active pattern AP1 and the second active pattern AP2 may be exposed. The spacer pattern 121 and the first lower mask film 11 may be removed using a planarization process, but example embodiments of the present disclosure are not limited thereto.

Referring to FIGS. 40 to 42, the sacrificial film 33 and the etching stop film 31 on the buried insulating layer 201 may be removed.

Through this, the buried insulating layer 201 may be exposed.

Referring to FIGS. 43 to 45, the gate insulating pattern GOX may be formed along the side wall of the first active pattern AP1, the side wall of the second active pattern AP2, an upper surface of the back-gate capping pattern 115, and an upper surface of the buried insulating layer 201.

The gate insulating pattern GOX may be deposited on the active layer 202 and the element separation film STI in the peripheral circuit region PCR. The gate insulating pattern GOX may be formed using at least one of physical vapor deposition (PVD) technology, thermal chemical vapor deposition (CVD) technology, low pressure chemical vapor deposition (LP-CVD) technology, plasma enhanced chemical vapor deposition (PE-CVD) technology, and atomic layer deposition (ALD) technology, but example embodiments of the present disclosure are not limited thereto.

Subsequently, the first word line WL1 and the second word line WL2 may be formed on the gate insulating pattern GOX. The first and second word lines WL1 and WL2 may be formed above the side walls of the first and second active patterns AP1 and AP2.

Forming the first and second word lines WL1 and WL2 may include depositing a gate conductive film on the gate insulating pattern GOX and then performing an anisotropic etching process on the gate conductive film. Here, a deposition thickness of the gate conductive film may be less than half a width of the word line trench WL_T of FIG. 26 and FIG. 27.

During the anisotropic etching process on the gate conductive film, the gate insulating pattern GOX may be used as an etching stop film. Unlike the drawings, the gate conductive film may be over-etched so that the buried insulating layer 201 is exposed. The first and second word lines WL1 and WL2 may have various shapes depending on the anisotropic etching process on the gate conductive film.

As an example, after the first and second word lines WL1 and WL2 are formed, a gas-phase doping (GPD) process or a plasma doping (PLAD) process may be performed. Through this, impurities may be doped into the first and second active patterns AP1 and AP2 through the gate insulating pattern GOX exposed by the first and second word lines WL1 and WL2.

Referring to FIGS. 46 to 48, a preliminary word line shielding insulating liner 155_P may be formed on the first and second word lines WL1 and WL2.

That is, the preliminary word line shielding insulating liner 155_P may be formed above the sub-substrate 200. The preliminary word line shielding insulating liner 155_P may cover surfaces of the word lines WL1 and WL2.

For example, the preliminary word line shielding insulating liner 155_P may include a silicon nitride (SiN) film, a silicon oxynitride (SiON) film, a silicon carbide (SiC) film, a silicon carbon nitride (SiCN) film, or a combination thereof.

Subsequently, the word line shielding conductive pattern SS may be formed to fill the word line trench WL_T of FIG. 26 and FIG. 27 in which the preliminary word line shielding insulating liner 155_P is formed.

Subsequently, a portion of the word line shielding conductive pattern SS may be removed by performing an etch-back process.

Referring to FIGS. 49 to 51, the word line shielding insulating capping film 154 may be formed on a recessed word line shielding conductive pattern SS.

For example, the word line shielding insulating capping film 154 may include silicon oxide, silicon oxynitride, silicon nitride, silicon carbide (SiC), silicon carbon nitride (SiCN), or a combination thereof.

Referring to FIGS. 52 to 54, a planarization process may be performed on the preliminary word line shielding insulating liner 155_P and the word line shielding insulating capping film 154 so that upper surfaces of the first and second word lines WL1 and WL2 are exposed. In this case, upper surfaces of the gate insulating pattern GOX may serve as an etching stop film.

For example, the planarization process may include a chemical mechanical polishing (CMP) process, but example embodiments of the present disclosure are not limited thereto and may be changed in various ways.

Subsequently, portions of the first and second word lines WL1 and WL2 may be removed by performing an etch-back process, and the second gate capping pattern 153 may be formed on recessed first and second word lines WL1 and WL2.

For example, the second gate capping pattern 153 may include silicon oxide, silicon oxynitride, silicon nitride, silicon carbide (SiC), silicon carbon nitride (SiCN), or a combination thereof.

Referring to FIGS. 55 to 57, a planarization process may be performed on upper surfaces of the gate insulating pattern GOX so that upper surfaces of the first and second active patterns AP1 and AP2 are exposed.

For example, the planarization process may include a chemical mechanical polishing (CMP) process, but example embodiments of the present disclosure are not limited thereto and may be changed in various ways.

Subsequently, the first dopant region SDR1 may be formed within the first and second active patterns AP1 and AP2.

An impurity may be doped into a portion of the first active pattern AP1 and a portion of the second active pattern AP2 so that the first dopant region SDR1 is formed.

Forming the first dopant region SDR1 may be an optional process. A subsequent manufacturing method will be described using a case where the first dopant region SDR1 is not formed.

Referring to FIGS. 58 to 60, the polysilicon pattern 161 may be formed above a front surface of the sub-substrate 200.

The polysilicon pattern 161 may contact the first and second active patterns AP1 and AP2 in the cell array region CAR. The polysilicon pattern 161 may be formed on the element separation film STI in the peripheral circuit region PCR.

Subsequently, a third mask pattern MP3 that exposes the peripheral circuit region PCR may be formed on the polysilicon pattern 161. The polysilicon pattern 161 of the peripheral circuit region PCR may be removed using the third mask pattern MP3 as an etching mask. The element separation film STI may be exposed in the peripheral circuit region PCR.

Referring to FIGS. 61 to 63, the metal pattern 163 and the bit line mask pattern 165 may be formed above or on the polysilicon pattern 161 of the cell array region CAR.

The metal pattern 163 and the bit line mask pattern 165 may be formed on the element separation film STI of the peripheral circuit region PCR.

Referring to FIGS. 64 to 66, the bit lines BL extending in the second direction D2 may be formed by patterning the bit line mask pattern 165, the metal pattern 163, and the polysilicon pattern 161.

While the bit lines BL are formed, a portion of the back-gate capping pattern 115 may be etched. Additionally, while the bit lines BL are formed, the element separation film STI of the peripheral circuit region PCR may be etched. Through this, a portion of the element separation film STI and the active layer 202 may be exposed.

Referring to FIGS. 67 to 69, the bit line shielding insulating liner 171 may be formed on the bit lines BL. The bit line shielding insulating liner 171 may define a bit line shielding region between the bit lines BL.

The bit line shielding insulating liner 171 may have a substantially uniform thickness. The bit line shielding insulating liner 171 may be formed above a front surface of the sub-substrate 200. A deposition thickness of the bit line shielding insulating liner 171 may be less than half a distance at which the bit lines BL are spaced apart. As the bit line shielding insulating liner 171 is formed, the bit line shielding region may be defined between the bit lines BL by the bit line shielding insulating liner 171. The bit line shielding region may extend in the second direction D2 parallel to the bit lines BL.

After the bit line shielding insulating liner 171 is formed, the bit line shielding conductive pattern SL may be formed within the bit line shielding region of the bit line shielding insulating liner 171.

The bit line shielding conductive pattern SL may be formed between the bit lines BL. For example, forming the bit line shielding conductive pattern SL may include forming a bit line shielding conductive film on the bit line shielding insulating liner 171 to fill the bit line shielding region, and recessing an upper surface of the bit line shielding conductive film.

According to some example embodiments, while the bit line shielding conductive pattern SL is formed, the connection portion SLc of the bit line shielding conductive pattern may be disposed in the peripheral circuit region PCR.

Referring to FIGS. 70 to 72, the bit line shielding insulating capping film 175 may be formed on the bit line shielding conductive pattern SL.

Additionally, the bit line shielding insulating capping film 175 may cover the connection portion SLc of the bit line shielding conductive pattern in the peripheral circuit region PCR.

Forming the bit line shielding insulating capping film 175 may include forming a bit line shielding capping insulating film that fills the bit line shielding region where the bit line shielding conductive pattern SL is formed. In addition, forming the bit line shielding insulating capping film 175 may include performing a planarization process on the bit line shielding capping insulating film and the bit line shielding insulating liner 171 to expose an upper surface of the bit lines BL that is an upper surface of the bit line mask pattern 165.

Although not shown in the drawings, the bonding insulating film 263 of FIG. 74 and FIG. 75 described below may be further formed on the bit line shielding insulating capping film 175, the bit line shielding insulating liner 171, and the bit line BL.

Referring to FIGS. 73 to 75, the sub-substrate 200 where the first and second back gate electrodes BG1 and BG2, the first and second word lines WL1 and WL2, the first and second active patterns AP1 and AP2, and the bit lines BL may be bonded to the substrate 100 where the peripheral gate structure PG is formed.

The substrate 100 and the sub-substrate 200 may be bonded using the bonding insulating film 263.

For example, because each of the first and second active patterns AP1 and AP2 is made of a monocrystalline semiconductor material, the word line shielding structure GSS having a complex structure may be formed between the first and second word lines WL1 and WL2. In addition, by forming the word line shielding structure GSS and the bit line shielding structure 171, SL, and 175 on the first and second active patterns AP1 and AP2 and then bonding the word line shielding structure GSS and the bit line shielding structure 171, SL, and 175 to the peripheral gate structure PG through wafer bonding, the word line shielding structure GSS having the complex structure and the bit line shielding structure 171, SL, and 175 may be implemented above the peripheral gate structure PG.

Referring to FIGS. 76 to 78, after the substrate 100 and the sub-substrate 200 are bonded, a rear surface lapping process removing the sub-substrate 200 may be performed.

Removing the sub-substrate 200 may include sequentially performing a grinding process and a wet etching process to expose the buried insulating layer 201.

Referring to FIGS. 79 to 81, the first active pattern AP1 and the second active pattern AP2 may be exposed by removing the buried insulating layer 201.

The buried insulating layer 201 may be removed so that a portion of the gate insulating pattern GOX and a portion of the back-gate insulating pattern 113 are exposed.

Subsequently, the exposed gate insulating pattern GOX and the exposed back-gate insulating pattern 113 may be removed. Through this, the first and second back gate electrodes BG1 and BG2, the first word line WL1, and the second word line WL2 may be exposed.

Subsequently, a portion of each of the first and second back gate electrodes BG1 and BG2, a portion of the first word line WL1, and a portion of the second word line WL2 may be removed by performing an etch-back process.

Subsequently, the back-gate separation pattern 111 may be formed on recessed first and second back gate electrodes BG1 and BG2. Additionally, the first gate capping pattern 143 may be formed on recessed first and second word lines WL1 and WL2. The back-gate separation pattern 111 and the first gate capping pattern 143 may be simultaneously formed.

In the peripheral circuit region PCR, an insertion insulating film 213 may be formed on the element separation film STI and the active layer 202. As an example, the insertion insulating film 213 may be the remaining portion remaining after removing the buried insulating layer 201. As another example, after the back-gate separation pattern 111 and the first gate capping pattern 143 are formed, the insertion insulating film 213 that exposes the cell array region CAR may be formed.

Referring to FIGS. 82 to 84, the lower contact etching stop film 211, the upper contact etching stop film 212, and the contact interlayer insulating film 231 may be sequentially formed above a front surface of the substrate 100.

Subsequently, contact holes exposing the first active pattern AP1 and the second active pattern AP2 may be formed within the lower contact etching stop film 211, the upper contact etching stop film 212, and the contact interlayer insulating film 231. The contact pattern BC may be formed within the contact hole. The contact patterns BC may be formed on the first active pattern AP1 and the second active pattern AP2. The contact patterns BC may be connected to the first active pattern AP1 and the second active pattern AP2.

Unlike the drawings, a contact film contacting the first active pattern AP1 and the second active pattern AP2 may be formed above the front surface of the substrate 100. Subsequently, the contact pattern BC may be formed by patterning the contact film. The contact separation pattern may be formed between the contact patterns BC spaced apart from each other.

Referring to FIG. 85, a lower peripheral contact plug hole may be formed in the peripheral circuit region PCR.

The lower peripheral contact plug hole may expose the metal pattern 163 disposed at an end portion of the bit line BL, the connection portion SLc of the bit line shielding conductive pattern SL, and the peripheral wire line 241a. The lower peripheral contact plug hole may be formed through the element separation film STI.

Subsequently, in FIG. 3 and FIG. 4, lower peripheral contact plugs LPLGa, LPLGb, and LPLGc may be formed within the lower peripheral contact plug hole.

Subsequently, the data storage patterns DSP may be formed on the contact patterns BC.

While this disclosure has been described in connection with what is presently considered to be some example embodiments, it is to be understood that the disclosure is not limited to the disclosed example embodiments, but, on the contrary, is intended to cover various modifications and equivalent arrangements included within the spirit and scope of the appended claims.

### DESCRIPTION OF SYMBOLS

What is claimed is:

1. A semiconductor memory device, comprising:
a peripheral gate structure on a substrate;
bit lines above the peripheral gate structure, the bit lines being spaced apart from each other in a first direction, the bit lines extending in a second direction different from the first direction;
a first active pattern and a second active pattern above the bit lines, the first active pattern and the second active pattern being spaced apart from each other in the second direction;
a first word line and a second word line between the first active pattern and the second active pattern, the first word line being adjacent to the first active pattern, the second word line being adjacent to the second active pattern;
a first back gate electrode corresponding to the first word line, the first active pattern being between the first back gate electrode and the first word line;
a second back gate electrode corresponding to the second word line, the second active pattern being between the second back gate electrode and the second word line; and
a word line shielding structure between the first word line and the second word line.

2. The semiconductor memory device of claim 1, wherein an interval between the first word line and the second word line in the second direction is 10 nm or less.

3. The semiconductor memory device of claim 1, wherein an interval between the first word line and the second word line in the second direction is 6 nm or less.

4. The semiconductor memory device of claim 1, wherein the word line shielding structure comprises:
a word line shielding conductive pattern; and
a word line shielding insulating liner including a first portion between the word line shielding conductive pattern and the first word line and a second portion between the word line shielding conductive pattern and the second word line.

5. The semiconductor memory device of claim 4, wherein a length of the word line shielding conductive pattern in the second direction is 2 nm or less.

6. The semiconductor memory device of claim 4, wherein a length of the word line shielding insulating liner in the second direction is 2 nm or less.

7. The semiconductor memory device of claim 4, wherein the word line shielding conductive pattern includes a conductive material including conductive metal nitride, conductive metal silicon nitride, metal carbonitride, conductive metal silicide, conductive metal oxide, a two-dimensional material, a metal, or a combination thereof.

8. The semiconductor memory device of claim 4, wherein the word line shielding insulating liner includes an insulating material including a silicon nitride (SiN) film, a silicon oxynitride (SiON) film, a silicon carbide (SiC) film, a silicon carbon nitride (SiCN) film, or a combination thereof.

9. The semiconductor memory device of claim 4, wherein the word line shielding conductive pattern extends in a third direction different from the first direction and the second direction and overlaps the first word line and the second word line in the second direction.

10. The semiconductor memory device of claim 9, wherein a length of the word line shielding conductive pattern in the third direction is equal to or greater than a length of each of the first word line and the second word line in the third direction.

11. The semiconductor memory device of claim 10, wherein a height of a lower end portion of the word line shielding conductive pattern in the third direction is equal to or less than a height of a lower end portion of each of the first word line and the second word line in the third direction, and a height of an upper end portion of the word line shielding conductive pattern in the third direction is equal to or greater than a height of an upper end portion of each of the first word line and the second word line in the third direction.

12. The semiconductor memory device of claim 9, wherein the word line shielding conductive pattern extends in the third direction and overlaps the first back gate electrode and the second back gate electrode in the second direction.

13. The semiconductor memory device of claim 1, further comprising:
a bit line shielding structure being adjacent to an adjacent one of the bit lines and above the peripheral gate structure, the bit line shielding structure extending in the second direction.

14. The semiconductor memory device of claim 13, wherein the bit line shielding structure includes a bit line shielding conductive pattern and a bit line shielding insulating liner, the bit line shielding liner being between the bit line shielding conductive pattern and the bit line.

15. The semiconductor memory device of claim 1, wherein each of the first active pattern and the second active pattern is made of a monocrystalline semiconductor material.

16. The semiconductor memory device of claim 1, further comprising:
a bonding insulating film between the peripheral gate structure and the bit lines.

17. A semiconductor memory device, comprising:
a peripheral gate structure on a substrate;
bit lines above the peripheral gate structure, the bit lines being spaced apart from each other in a first direction, the bit lines extending in a second direction different from the first direction;
a first active pattern and a second active pattern above the bit lines, the first active pattern and the second active pattern being spaced apart from each other in the second direction;
a first word line and a second word line between the first active pattern and the second active pattern, the first word line being adjacent to the first active pattern, the second word line being adjacent to the second active pattern;
a first back gate electrode corresponding to the first word line, the first active pattern being between the first back gate electrode and the first word line; and
a second back gate electrode corresponding to the second word line, the second active pattern being between the second back gate electrode and the second word line,
wherein an interval between the first word line and the second word line in the second direction is 6 nm or less.

18. The semiconductor memory device of claim 17, further comprising:
a word line shielding structure between the first word line and the second word line.

19. The semiconductor memory device of claim 18,
wherein the word line shielding structure comprises,
a word line shielding conductive pattern, and
a word line shielding insulating liner being between the word line shielding conductive pattern and the first word line and being between the word line shielding conductive pattern and the second word line, and
wherein the word line shielding conductive pattern extends in a third direction different from the first direction and the second direction, and overlaps the first word line and the second word line in the second direction.

20. A semiconductor memory device, comprising:
a peripheral gate structure on a substrate;
bit lines above the peripheral gate structure, the bit lines being spaced apart from each other in a first direction, the bit lines extending in a second direction different from the first direction;
a bit line shielding structure being adjacent to an adjacent one of the bit lines and above the peripheral gate structure, the bit line shielding structure extending in the second direction;
a first active pattern and a second active pattern above the bit lines, the first active pattern and the second active pattern being spaced apart from each other in the second direction;
a first word line and a second word line between the first active pattern and the second active pattern, the first word line being adjacent to the first active pattern, the second word line being adjacent to the second active pattern;
a first back gate electrode corresponding to the first word line, the first active pattern being between the first back gate electrode and the first word line;
a second back gate electrode corresponding to the second word line, the second active pattern being between the second back gate electrode and the second word line; and
a word line shielding structure between the first word line and the second word line,
wherein an interval between the first word line and the second word line in the second direction is 6 nm or less.
